(19) United States
(12) Patent Application Publication
(10) Pub. No.: US 2026/0173548 A1
(43) Pub. Date: Jun. 18, 2026

(54) ELECTROMAGNETIC WAVE DETECTOR AND ELECTROMAGNETIC WAVE DETECTOR ARRAY

(71) Applicant: Mitsubishi Electric Corporation, Tokyo (JP)

(72) Inventors: Shoichiro FUKUSHIMA, Chiyoda-ku, Tokyo (JP); Masaaki SHIMATANI, Chiyoda-ku, Tokyo (JP); Satoshi OKUDA, Chiyoda-ku, Tokyo (JP); Shimpei OGAWA, Chiyoda-ku, Tokyo (JP)

(73) Assignee: Mitsubishi Electric Corporation, Tokyo (JP)

(21) Appl. No.: 19/126,657

(22) PCT Filed: Nov. 9, 2022
(86) PCT No.: PCT/JP2022/041662

§ 371 Date: May 2, 2025

(51) Int. Cl. H10F 30/21; H10F 71/00

(52) U.S. Cl. CPC H10F 30/288; H10F 71/00

(57) ABSTRACT

An electromagnetic wave detector includes a first photosensitizing layer, a first electrode portion, a first insulating layer, a two-dimensional material layer, a second electrode portion, and a second photosensitizing layer. The first insulating layer is provided on the first photosensitizing layer. The two-dimensional material layer is provided on the first insulating layer. The two-dimensional material layer is electrically connected to the first photosensitizing layer. The first photosensitizing layer is connected to the two-dimensional material layer. The second photosensitizing layer has an absorption maximum value in a wavelength range different from that of the first photosensitizing layer. The second photosensitizing layer causes a voltage change in the wavelength range different from that of the first photosensitizing layer. The first insulating layer is disposed between the first photosensitizing layer and the two-dimensional material layer.

### TECHNICAL FIELD

The present disclosure relates to an electromagnetic wave detector and an electromagnetic wave detector array.

### BACKGROUND ART

Graphene, which is an example of the two-dimensional material layer, is known as a material of an electromagnetic wave detection layer used for a next-generation electromagnetic wave detector. The graphene is extremely high in mobility. The graphene has an absorptivity as low as 2.3%. Thus, a sensitivity enhancement technique for an electromagnetic wave detector including the graphene as the two-dimensional material layer has been proposed.

Japanese National Patent Publication No. 2013-506303 (PTL 1) proposes a photodetector (electromagnetic wave detector) including a first group of photodiodes (first photosensitizing layer) and a second group of photodiodes (second photosensitizing layer). The photodiodes of the second group are configured to output signals in response to incident photons in a second wavelength range different from the wavelength range of the photodiodes of the first group. Thus, the photodetector can detect each of the detection wavelength of the photodiodes of the first group and the detection wavelength of the photodiodes of the second group. Quantum dots are used for the photodiodes.

### CITATION LIST

### Patent Literature

PTL 1: Japanese National Patent Publication No. 2013-506303

### SUMMARY OF INVENTION

### Technical Problem

However, the sensitivity of the electromagnetic wave detector cannot be improved, resulting in a low sensitivity of the electromagnetic wave detector.

The present disclosure has been made in view of the above problem. An object of the present disclosure is to provide an electromagnetic wave detector and an electromagnetic wave detector array that have high sensitivity.

### Solution to Problem

An electromagnetic wave detector according to the present disclosure includes a first photosensitizing layer, a first electrode portion, a first insulating layer, a two-dimensional material layer, a second electrode portion, and a second photosensitizing layer. The first electrode portion is electrically connected to the first photosensitizing layer. The first insulating layer is provided on the first photosensitizing layer. The two-dimensional material layer is provided on the first insulating layer. The two-dimensional material layer is electrically connected to the first photosensitizing layer. The second electrode portion is electrically connected to the two-dimensional material layer. The first photosensitizing layer is connected to the two-dimensional material layer. The second photosensitizing layer has an absorption maximum value in a wavelength range different from that of the first photosensitizing layer. The second photosensitizing layer causes a voltage change in the wavelength range different from that of the first photosensitizing layer. The first insulating layer is disposed between the first photosensitizing layer and the two-dimensional material layer.

### Advantageous Effects of Invention

The electromagnetic wave detector according to the present disclosure can have high sensitivity.

### BRIEF DESCRIPTION OF DRAWINGS

FIG. 1 is a top view schematically showing a configuration of an electromagnetic wave detector according to Embodiment 1.

FIG. 2 is a sectional view taken along the line II-II of FIG. 1.

FIG. 3 is a flowchart schematically showing a method of manufacturing an electromagnetic wave detector according to Embodiment 1.

FIG. 4 is a sectional view schematically showing a configuration of an electromagnetic wave detector according to Embodiment 2.

FIG. 5 is a sectional view schematically showing a configuration of an electromagnetic wave detector according to Embodiment 3.

FIG. 6 is a sectional view schematically showing a configuration of an electromagnetic wave detector according to Embodiment 4.

FIG. 7 is a sectional view schematically showing a configuration of an electromagnetic wave detector according to Embodiment 5.

FIG. 8 is a sectional view schematically showing a configuration of an electromagnetic wave detector according to Embodiment 6.

FIG. 9 is a sectional view schematically showing a configuration of an electromagnetic wave detector according to Embodiment 7.

FIG. 10 is a sectional view schematically showing a configuration of an electromagnetic wave detector according to Embodiment 8.

FIG. 11 is a sectional view schematically showing a configuration of an electromagnetic wave detector according to Embodiment 9.

FIG. 12 is a sectional view schematically showing a configuration of an electromagnetic wave detector according to Embodiment 10.

FIG. 13 is a sectional view schematically showing a configuration of an electromagnetic wave detector according to Embodiment 11.

FIG. 14 is a sectional view schematically showing a configuration of an electromagnetic wave detector according to Modification 1 of Embodiment 11.

FIG. 15 is a sectional view schematically showing a configuration of an electromagnetic wave detector according to Modification 2 of Embodiment 11.

FIG. 16 is a sectional view schematically showing a configuration of an electromagnetic wave detector according to Modification 3 of Embodiment 11.

FIG. 17 is a sectional view schematically showing a configuration of an electromagnetic wave detector according to Modification 4 of Embodiment 11.

FIG. 18 is a sectional view schematically showing a configuration of an electromagnetic wave detector according to Modification 5 of Embodiment 11.

FIG. 19 is a schematic view showing a configuration of an electromagnetic wave detector array according to Embodiment 12.

FIG. 20 is a schematic view showing a configuration of an electromagnetic wave detector array according to a modification of Embodiment 12.

### DESCRIPTION OF EMBODIMENTS

Embodiments will be described below with reference to the drawings. In the following description, the same or corresponding components are denoted by the same reference characters, and redundant description will not be repeated.

In the embodiments described below, the drawings are schematic and are intended to conceptually describe functions or structures. Further, the present disclosure is not limited to the embodiments described below. Unless otherwise specified, a basic configuration of the electromagnetic wave detector is common to all the embodiments. Further, the components denoted by the same reference characters are the same or equivalent components as described above. This is common throughout the specification.

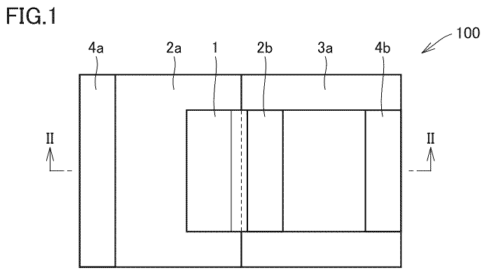

Although a configuration of an electromagnetic wave detector 100 in detection of visible light or infrared light will be described below in the embodiments with reference to FIG. 1, the present disclosure is not limited thereto. Electromagnetic wave detector 100 of each of the embodiments described below is also effective as a detector that detects radio waves such as X-rays, ultraviolet light, near-infrared light, terahertz (THz) waves, or microwaves in addition to the visible light and the infrared light. It should be noted that the light and the radio waves will be collectively referred to as electromagnetic waves in the present disclosure.

In the present disclosure, the term “p-type graphene” or “n-type graphene” may be used as the graphene. In the embodiments described below, graphene having a larger number of holes than those of graphene in an intrinsic state is referred to as p-type graphene. Graphene having a larger number of electrons than those of graphene in the intrinsic state is referred to as n-type graphene.

In the present disclosure, the term “n-type” or “p-type” may be used to refer to the material of a member that is in contact with graphene, which is an example of a two-dimensional material layer 1. An n-type material refers to, for example, a material that has an electron-donating property. A p-type material refers to, for example, a material that has an electron-withdrawing property. In addition, a material in which there is a bias in charge throughout molecules and in which electrons are dominant may be referred to as an n-type material. A material in which there is a bias in charge throughout molecules and in which holes are dominant may be referred to as a p-type material. The n-type material and the p-type material may be any one of an organic substance and an inorganic substance, or a mixture thereof.

In the present disclosure, a layer in which no tunnel current is generated is referred to as an insulating layer. A layer in which a tunnel current can occur is referred to as a buffer layer.

Further, a plasmon resonance phenomenon such as a surface plasmon resonance phenomenon, which is an interaction between a metal surface and light, a phenomenon referred to as a pseudo surface plasmon resonance, which means a resonance for a metal surface in a range other than a visible light range and a near-infrared light range, and a phenomenon referred to as metamaterial or plasmonic metamaterial, which means manipulation of a wavelength by a structure having a size equal to or less than a wavelength, will not be particularly distinguished from one another by the names and will be handled equivalently in terms of effects exerted by the phenomena. In the present disclosure, these resonances will be referred to as a surface plasmon resonance, a plasmon resonance, or, merely, a resonance.

### Embodiment 1

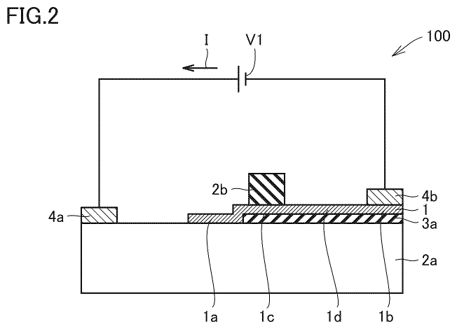

A configuration of electromagnetic wave detector 100 according to Embodiment 1 will be described with reference to FIGS. 1 and 2.

As shown in FIG. 1, electromagnetic wave detector 100 includes two-dimensional material layer 1, a first photosensitizing layer 2a, a second photosensitizing layer 2b, a first insulating layer 3a, a first electrode portion 4a, and a second electrode portion 4b.

As shown in FIG. 2, two-dimensional material layer 1 is provided on first insulating layer 3a. Two-dimensional material layer 1 is electrically connected to first photosensitizing layer 2a. Two-dimensional material layer 1 extends from the top surface of first photosensitizing layer 2a to the top surface of first insulating layer 3a. Two-dimensional material layer 1 is electrically connected to second electrode portion 4b.

More specifically, two-dimensional material layer 1 includes a first portion 1a, a second portion 1b, a third portion 1c, and a fourth portion 1d. First portion 1a is electrically connected to first photosensitizing layer 2a. First portion 1a is disposed on first photosensitizing layer 2a. Desirably, first portion 1a is joined to first photosensitizing layer 2a by a Schottky junction.

Second portion 1b is retained between first insulating layer 3a and second electrode portion 4b. Second portion 1b is electrically connected to second electrode portion 4b. Second portion 1b is disposed on first insulating layer 3a.

Third portion 1c is electrically connected to second photosensitizing layer 2b between first portion 1a and second portion 1b. Third portion 1c is disposed on second photosensitizing layer 2b. Desirably, third portion 1c is joined to second photosensitizing layer 2b by a Schottky junction. Further, third portion 1c is disposed on first insulating layer 3a, but it may also be disposed on two-dimensional material layer 1. In this case, it is preferable that third portion 1c be joined to each of first photosensitizing layer 2a and second photosensitizing layer 2b by a Schottky junction.

Fourth portion 1d is the region between first portion 1a and second portion 1b, excluding third portion 1c. Fourth portion 1d is disposed on the top surface of first insulating layer 3a and on the inner surface of an opening of first insulating layer 3a. The opening is the region that exposes first photosensitizing layer 2a. First insulating layer 3a separates fourth portion 1d from first photosensitizing layer 2a.

The thicknesses of first portion 1a, second portion 1b, third portion 1c, and fourth portion 1d of two-dimensional material layer 1 may be equal to one another. The top surface of two-dimensional material layer 1 may have unevenness caused by first portion 1a, second portion 1b, third portion 1c, and fourth portion 1d. The distance between the bottom surface of first portion 1a and the bottom surface of first photosensitizing layer 2a is less than the distance between the top surface of second portion 1b, third portion 1c, fourth portion 1d and the bottom surface of first photosensitizing layer 2a. The distance between the bottom surface of third portion 1c and the bottom surface of second photosensitizing layer 2b is less than the distance between the top surface of third portion 1c and the bottom surface of first photosensitizing layer 2a.

First photosensitizing layer 2a is electrically connected to two-dimensional material layer 1. First photosensitizing layer 2a has an absorption maximum value in the wavelength range of the electromagnetic waves to be detected by electromagnetic wave detector 100.

Second photosensitizing layer 2b is connected to two-dimensional material layer 1. In the present embodiment, second photosensitizing layer 2b is electrically connected to two-dimensional material layer 1. Second photosensitizing layer 2b is provided on the top surface of two-dimensional material layer 1. Second photosensitizing layer 2b and first insulating layer 3a retain two-dimensional material layer 1 in between.

Second photosensitizing layer 2b has an absorption maximum value in the wavelength range of the electromagnetic waves to be detected by electromagnetic wave detector 100. Second photosensitizing layer 2b has an absorption maximum value in a wavelength range different from that of first photosensitizing layer 2a. Second photosensitizing layer 2b that can cause a voltage change in the wavelength range different from that of first photosensitizing layer 2a.

The wavelength range of the electromagnetic waves to be detected by electromagnetic wave detector 100 according to the present embodiment is the sum of the wavelength range of the electromagnetic waves to be detected by first photosensitizing layer 2a and the wavelength range of the electromagnetic waves to be detected by second photosensitizing layer 2b. The wavelength range of the electromagnetic waves to be detected by second photosensitizing layer 2b may have overlapping wavelengths as long as they have wavelengths different from those of the electromagnetic waves to be detected by first photosensitizing layer 2a.

First insulating layer 3a is provided on first photosensitizing layer 2a. First insulating layer 3a is disposed between first photosensitizing layer 2a and two-dimensional material layer 1. First insulating layer 3a may be directly retained between first photosensitizing layer 2a and the two-dimensional material layer.

First electrode portion 4a is provided on first photosensitizing layer 2a. First electrode portion 4a is electrically connected to first photosensitizing layer 2a. First electrode portion 4a may be directly connected to two-dimensional material layer 1.

Second electrode portion 4b is provided on two-dimensional material layer 1. Second electrode portion 4b is electrically connected to two-dimensional material layer 1. Second electrode portion 4b and first insulating layer 3a retain two-dimensional material layer 1 in between.

Although not shown, electromagnetic wave detector 100 described above may be disposed as a first electromagnetic wave detector, and a second electromagnetic wave detector having the same configuration as that of the first electromagnetic wave detector may be further disposed. The first electromagnetic wave detector is disposed in a space irradiated with electromagnetic waves. The second electromagnetic wave detector is disposed in a space shielded from electromagnetic waves. Electromagnetic waves may be detected by detecting the difference between the current of the first electromagnetic wave detector and the current of the second electromagnetic wave detector. Electromagnetic waves may be detected by detecting the difference between the voltage of the first electromagnetic wave detector and the voltage of the second electromagnetic wave detector.

Although not shown, an output amplification circuit including graphene may be provided on the same substrate as that of electromagnetic wave detector 100. The output amplification circuit including graphene has a higher operating speed than that of an output amplification circuit including a silicon-based semiconductor material. Thus, high-performance electromagnetic wave detector 100 can be achieved. In addition, as graphene is used for a peripheral circuit such as a readout circuit, as in the case of two-dimensional material layer 1, high-speed reading and simplification of a manufacturing process are achieved.

First electrode portion 4a, two-dimensional material layer 1, first photosensitizing layer 2a, and second electrode portion 4b are electrically connected in this order. Although not shown, a voltmeter for measuring voltage may be electrically connected between first electrode portion 4a and second electrode portion 4b. The voltmeter is a circuit for detecting a voltage change caused by electromagnetic wave irradiation. In addition, a current meter for measuring current may be electrically connected between first electrode portion 4a and second electrode portion 4b. It is only required that at least one of the voltmeter and the ammeter be electrically connected between first electrode portion 4a and second electrode portion 4b.

Next, the configurations of two-dimensional material layer 1, the electrode portions, the insulating portions, and the photosensitizing layers will be described in detail.

### <Configuration of Two-Dimensional Material Layer 1>

The material of two-dimensional material layer 1 is graphene. The material of two-dimensional material layer 1 may be single-layer graphene. In this case, since the single-layer graphene has a higher carrier mobility than that of a conventional semiconductor material, the optical response speed is improved more than an electromagnetic wave detector 100 including the conventional semiconductor material.

The material of two-dimensional material layer 1 may be two or more layers of graphene. In this case, the orientation of the photon vector of the hexagonal lattice of graphene in each layer may be the same or different. When two-dimensional material layer 1 is two or more layers of graphene, the size of the band gap can be adjusted according to the number of layers of graphene. Thus, the wavelength of the electromagnetic wave absorbed by two-dimensional material layer 1 can be selected. In addition, unlike conventional electromagnetic wave detectors, there is no need to adjust the band gap according to the composition of the semiconductor material, and the band gap can be adjusted by adjusting the number of layers of two-dimensional material layer 1, leading to simplification of the manufacturing process for electromagnetic wave detector 100.

Since the band gap size is adjusted by adjusting the number of layers of two-dimensional material layer 1, it is not necessary to use an optical filter, which is a typical wavelength selection method. Thus, the number of optical components can be reduced. This can also reduce a loss of incident light due to passing through the optical filter. In addition, photocarriers generated in two-dimensional material layer 1 can be detected as signals, thus improving the detection sensitivity of electromagnetic wave detector 100.

The material of two-dimensional material layer 1 may be nanoribbon-like graphene (graphene nanoribbon). The material of two-dimensional material layer 1 may be a single graphene nanoribbon. The material of two-dimensional material layer 1 may be stacked graphene nanoribbons, or a plurality of graphene nanoribbons periodically arranged on a plane. When the plurality of graphene nanoribbons are arranged periodically on a plane, a plasmon resonance occurs in the graphene, leading to an improved detection sensitivity of electromagnetic wave detector 100. This structure may be referred to as a graphene metamaterial, but the phenomenon is the same. Two-dimensional material layer 1 may be non-doped graphene or graphene doped with p-type or n-type impurities.

The embodiments described later will give description by taking graphene as an example of the material of two-dimensional material layer 1, but the material of two-dimensional material layer 1 is not limited to graphene. For example, the material such as transition metal dichalcogenide (TMD), black phosphorus, silicene (a two-dimensional honeycomb structure composed of silicon atoms), or germanene (a two-dimensional honeycomb structure composed of germanium atoms) can be used as the material of two-dimensional material layer 1. Examples of the transition metal dichalcogenide include transition metal dichalcogenide such as MoS₂, WS₂, and WSe₂.

These materials are materials which have a structure similar to that of the graphene and in which atoms can be arranged in a single layer within a two-dimensional plane. Thus, also when these materials are applied to two-dimensional material layer 1, the same functions and effects can be obtained as in the case where the graphene is applied to two-dimensional material layer 1.

A protective film (not shown) may be provided on two-dimensional material layer 1. The protective film (not shown) may be provided on first photosensitizing layer 2a so as to cover the surroundings of two-dimensional material layer 1, first insulating layer 3a, second photosensitizing layer 2b, and second electrode portion 4b. The material of the protective film may be any material, and for example, is an insulating layer containing silicon oxide (SiO₂). The material of the protective film is an insulator such as an oxide or a nitride. Examples of the material of the protective film include silicon oxide (SiO₂), silicon nitride (SiN), hafnium oxide (HfO₂), aluminum oxide (Al₂O₃), and boron nitride (BN).

As two-dimensional material layer 1 comes into contact with second electrode portion 4b, photocarriers are doped from second electrode portion 4b to two-dimensional material layer 1. For example, when two-dimensional material layer 1 is graphene and second electrode portion 4b is gold (Au), the photocarriers are holes. The difference between the work function of graphene and the work function of gold (Au) causes holes to be doped in the portion of two-dimensional material layer 1 which is in contact with second electrode portion 4b. When electromagnetic wave detector 100 is driven in an electronic conduction state with two-dimensional material layer 1 doped with holes, the mobility of the electrons flowing in the channel is reduced due to the influence of the holes. As a result, the contact resistance between two-dimensional material layer 1 and second electrode portion 4b increases. In particular, when the entire region of two-dimensional material layer 1 is formed of single-layer graphene, a large amount of photocarriers (doping amount) is injected from second electrode portion 4b to two-dimensional material layer 1. Thus, the mobility of electric field effect of electromagnetic wave detector 100 decreases significantly. Therefore, when the entire region of two-dimensional material layer 1 is formed of single-layer graphene, the performance of electromagnetic wave detector 100 decreases. In addition, the amount of photocarriers doped from first electrode portion 4a to the multilayer graphene is smaller than the amount of photocarriers doped from first electrode portion 4a to the single-layer graphene. For this reason, the portion of two-dimensional material layer 1, which is in contact with second electrode portion 4b and is easily doped with photocarriers, may be formed of the multilayer graphene. This can suppress an increase in contact resistance between two-dimensional material layer 1 and second electrode portion 4b. This can suppress a decrease in the mobility of electric field effect of electromagnetic wave detector 100, leading to improved performance of electromagnetic wave detector 100.

In addition, the single-layer graphene may be used in the region of two-dimensional material layer 1 other than the region connected to second electrode portion 4b. In this case, high carrier mobility derived from the single-layer graphene is obtained in the region other than the region of contact with second electrode portion 4b. As a result, the increase in contact resistance described above can be suppressed, and high carrier mobility can be maintained, leading to improved performance of electromagnetic wave detector 100.

Two-dimensional material layer 1 may include a turbostratic structure portion. The turbostratic structure portion is a structure including a stack of a plurality of graphene layers in a state in which the lattices of the plurality of graphene layers are mismatched. Two-dimensional material layer 1 may include the turbostratic structure portion as part of two-dimensional material layer 1, or the entire two-dimensional material layer 1 may be formed of the turbostratic structure portion.

### <Configurations of First Photosensitizing Layer 2a and Second Photosensitizing Layer 2b>

Desirably, at least one of first photosensitizing layer 2a and second photosensitizing layer 2b includes a semiconductor. Also, desirably, at least one of first photosensitizing layer 2a and second photosensitizing layer 2b includes an atomic layer material having a band gap.

In the present embodiment, the material of first photosensitizing layer 2a is a semiconductor material such as silicon (Si). Specifically, the material of first photosensitizing layer 2a is, for example, a silicon substrate doped with impurities. When the material of first photosensitizing layer 2a is a semiconductor material, desirably, the semiconductor material is doped with impurities so as to have an electrical resistivity of 10 mΩ·cm or more. Doping of the semiconductor material at a low concentration increases the lifetime of the photocarriers generated in the semiconductor material in irradiation with light. As a result, the probability of photocarriers being injected into two-dimensional material layer 1 is improved. This can improve the optical sensitivity of electromagnetic wave detector 100.

Desirably, the thickness of first photosensitizing layer 2a and the thickness of second photosensitizing layer 2b are 10 μm or less. The thickness of first photosensitizing layer 2a and the thickness of second photosensitizing layer 2b may be reduced. As a result, the amount of deactivation of the photocarriers, which is generated in first photosensitizing layer 2a and second photosensitizing layer 2b in association with irradiation with electromagnetic waves and transported to two-dimensional material layer 1, decreases in first photosensitizing layer 2a and second photosensitizing layer 2b. This can improve the sensitivity of electromagnetic wave detector 100.

First photosensitizing layer 2a may have a multilayer structure. First photosensitizing layer 2a may be a pn junction photodiode, a pin photodiode, a Schottky photodiode, an avalanche photodiode, or any other photodiode. First photosensitizing layer 2a may be a phototransistor.

The material of first photosensitizing layer 2a is not limited to the material described above. The material of first photosensitizing layer 2a may be one or a combination of materials such as germanium (Ge), a compound semiconductor (e.g., a group III-V semiconductor or a group II-V semiconductor), mercury cadmium telluride (HgCdTe), indium antimonide (InSb), lead selenide (PbSe), lead sulfide (PbS), cadmium sulfide (CdS), gallium nitride (GaN), silicon carbide (SiC), gallium phosphide (GaP), indium gallium arsenide (InGaAs), or indium arsenide (InAs). The material of first photosensitizing layer 2a may be one or a combination of a substrate containing quantum wells or quantum dots, and a material such as a Type II superlattice.

The material of second photosensitizing layer 2b may be one or a combination of materials such as germanium (Ge), a compound semiconductor (e.g., a group III-V semiconductor or a group II-V semiconductor), mercury cadmium telluride (HgCdTe), indium antimonide (InSb), lead selenide (PbSe), lead sulfide (PbS), cadmium sulfide (CdS), gallium nitride (GaN), silicon carbide (SiC), gallium phosphide (GaP), indium gallium arsenide (InGaAs), or indium arsenide (InAs). The material of second photosensitizing layer 2b may be one or a combination of a substrate containing quantum wells or quantum dots, and a material such as a Type II superlattice.

The material of second photosensitizing layer 2b may be a quantum dot. Specifically, the material of second photosensitizing layer 2b may be a molybdenum disulfide (MoS₂) quantum dot, a tungsten disulfide (WS₂) quantum dot, a core-shell structured quantum dot of indium phosphide (InP) and zinc sulfide (ZnS), a core quantum dot of cadmium telluride (CdTe), a carbon quantum dot, a graphene quantum dot, a core-shell structured quantum dot of cadmium selenide (CdSe) and cadmium sulfide (CdS), a core-shell structured quantum dot of cadmium selenide (CdSe) and zinc sulfide (ZnS), a core-shell structured quantum dot of cadmium sulfide (CdS) and zinc sulfide (ZnS), a perovskite (APbX3 [A=Cs, MA (methylammonium), FA (formamidinium), X=Cl, Br, I)] quantum dot, a lead sulfide (PbS) quantum dot, or a core quantum dot of lead sulfide (PbS).

When silicon (Si) and gallium phosphide (GaP) are used as the material of either first photosensitizing layer 2a or second photosensitizing layer 2b, the range of wavelengths detected by electromagnetic wave detector 100 is as follows. In other words, the range of wavelengths detected by electromagnetic wave detector 100 is 0.1 μm or more and 1.1 μm or less, which is a combination of a typical absorption wavelength range of silicon (Si) of 0.2 μm or more and 1.1 μm or less and a typical absorption wavelength range of gallium phosphide (GaP) of 0.1 μm or more and 0.6 μm or less.

When germanium is used as the material of either first photosensitizing layer 2a or second photosensitizing layer 2b, the range of the detection wavelengths is 0.8 μm or more and 1.8 μm or less. When indium gallium arsenide is used as the material of either first photosensitizing layer 2a or second photosensitizing layer 2b, the detection wavelength range is 0.7 μm or more and 2.55 μm or less. When indium arsenide is used as the material of either first photosensitizing layer 2a or second photosensitizing layer 2b, the detection wavelength range is 1 μm or more and 3.1 μm or less. When indium antimonide is used as the material of either first photosensitizing layer 2a or second photosensitizing layer 2b, the detection wavelength range is 1 μm or more and 5.4 μm or less. When mercury cadmium telluride is used as the material of either first photosensitizing layer 2a or second photosensitizing layer 2b, the detection wavelength range is 2 μm or more and 16 μm or less.

The detection wavelength range when the quantum dots are used for second photosensitizing layer 2b depends on the material used and the size of the quantum dots. For example, a typical detection wavelength that provides the maximum quantum yield when the molybdenum disulfide (MoS₂) quantum dots are used for second photosensitizing layer 2b is 0.3 μm. A typical detection wavelength that provides the maximum quantum yield when the tungsten sulfide (WS₂) quantum dots are used for second photosensitizing layer 2b is 0.4 μm. A typical detection wavelength that provides the maximum quantum yield when the core-shell structured quantum dots of indium phosphide (InP) and zinc sulfide (ZnS) are used for second photosensitizing layer 2b is 0.4 μm. A typical detection wavelength that provides the maximum quantum yield when the core quantum dots of cadmium telluride (CdTe) are used for second photosensitizing layer 2b is 0.4 μm. A typical detection wavelength that provides the maximum quantum yield when the carbon quantum dots are used for second photosensitizing layer 2b is 0.4 μm. A typical detection wavelength that provides the maximum quantum yield when the graphene quantum dots are used for second photosensitizing layer 2b is 0.4 μm. A typical detection wavelength that provides the maximum quantum yield when the core-shell structured quantum dots of cadmium selenide (CdSe) and cadmium sulfide (CdS) are used for second photosensitizing layer 2b is 0.6 μm. A typical detection wavelength that provides the maximum quantum yield when the core-shell structured quantum dots of cadmium selenide (CdSe) and zinc sulfide (ZnS) are used for second photosensitizing layer 2b is 0.6 μm. A typical detection wavelength that provides the maximum quantum yield when the core-shell structured quantum dots of cadmium sulfide (CdS) and zinc sulfide (ZnS) are used for second photosensitizing layer 2b is 0.6 μm. A typical detection wavelength that provides the maximum quantum yield when the perovskite (APbX3 [A=Cs, MA (methylammonium), FA (formamidinium), X=Cl, Br, I]) quantum dots are used for second photosensitizing layer 2b is 0.6 μm. A typical detection wavelength that provides the maximum quantum yield when the quantum dots of lead sulfide (PbS) are used for second photosensitizing layer 2b is 1.2 μm. A typical detection wavelength that provides the maximum quantum yield when the core quantum dots of lead sulfide (PbS) are used for second photosensitizing layer 2b is 2.0 μm.

The detection wavelength range of electromagnetic wave detector 100 is the range obtained by combining the detection wavelength of the material of first photosensitizing layer 2a and the detection wavelength of the material of second photosensitizing layer 2b described above.

### <Configuration of First Insulating Layer 3a>

The material of first insulating layer 3a is, for example, silicon oxide (SiO₂). The material of first insulating layer 3a is not limited to silicon oxide, and may be, for example, tetraethyl orthosilicate (Si(OC₂H5)₄), silicon nitride (Si₃N₄), hafnium oxide (HfO₂), aluminum oxide (Al₂O₃), nickel oxide (NiO), boron nitride (BN), or a siloxane-based polymer. For example, the atomic arrangement of boron nitride (BN) is similar to the atomic arrangement t of graphene. Thus, when boron nitride (BN) comes into contact with two-dimensional material layer 1, which is made of graphene, a decrease in the electron mobility of two-dimensional material layer 1 is suppressed. Therefore, boron nitride (BN) is suitable for first insulating layer 3a, which is a base film disposed under two-dimensional material layer 1.

The thickness of first insulating layer 3a is not particularly limited, as long as first electrode portion 4a is electrically insulated from first photosensitizing layer 2a and no tunnel current is generated between first electrode portion 4a and first photosensitizing layer 2a. As the thickness of first insulating layer 3a is smaller, the electric field of two-dimensional material layer 1 changes by a greater degree due to the photocarriers generated at the interface between first insulating layer 3a and first photosensitizing layer 2a. For this reason, desirably, the thickness of first insulating layer 3a is as thin as possible.

### <Configurations of First Electrode Portion 4a and Second Electrode Portion 4b>

The materials of first electrode portion 4a and second electrode portion 4b can be any material that is a conductor. The materials of first electrode portion 4a and second electrode portion 4b may include, for example, at least one of gold (Au), silver (Ag), copper (Cu), aluminum (Al), nickel (Ni), chromium (Cr), and palladium (Pd). An adhesion layer (not shown) may be provided between first electrode portion 4a and first photosensitizing layer 2a or between second electrode portion 4b and first insulating layer 3a. The adhesion layer is configured to enhance adhesion. The material of the adhesion layer includes, for example, a metal material such as chromium (Cr) or titanium (Ti).

First electrode portion 4a is disposed on the front surface of first photosensitizing layer 2a in FIG. 2, but the present disclosure is not limited thereto as long as first electrode portion 4a is electrically connected to first photosensitizing layer 2a. For example, first electrode portion 4a may be electrically connected to the side surface or the bottom surface of first photosensitizing layer 2a. When first electrode portion 4a is electrically connected to the bottom surface of first photosensitizing layer 2a, in irradiation with electromagnetic waves from the top surface side of first photosensitizing layer 2a, the electromagnetic waves that are transmitted without being absorbed by first photosensitizing layer 2a can be reflected by first electrode portion 4a. This can increase the absorptivity of electromagnetic waves in first photosensitizing layer 2a and second photosensitizing layer 2b.

Second electrode portion 4b may be disposed on the top surface of two-dimensional material layer 1. In this case, the change in the shape of unevenness of two-dimensional material layer 1 is small in the region of contact between two-dimensional material layer 1 and second electrode portion 4b. Thus, a decrease in carrier mobility is suppressed because the occurrence of shape variations due to wrinkles or steps in two-dimensional material layer 1 is suppressed. Also, though not shown, second electrode portion 4b may be disposed on the bottom surface of two-dimensional material layer 1. In other words, second electrode portion 4b may be disposed on the top surface of first insulating layer 3a. In this case, the step of forming two-dimensional material layer 1 may be performed after the step of forming an electrode in the process of producing electromagnetic wave detector 100. Two-dimensional material layer 1 is thin compared with a bulk-shaped material, and accordingly, it is easily damaged in the formation step. Since the step of forming two-dimensional material layer 1 can be performed downstream, the risk of damage to two-dimensional material layer 1 is reduced, leading to an improved production yield of electromagnetic wave detector 100.

### <Method of Manufacturing Electromagnetic Wave Detector 100>

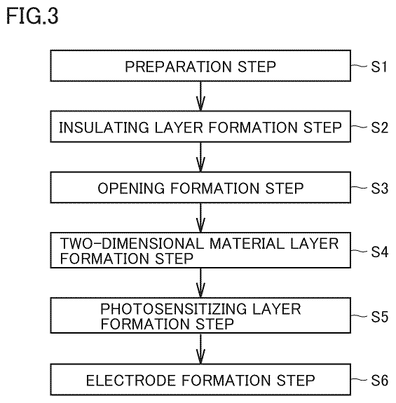

Next, the method of manufacturing electromagnetic wave detector 100 according to Embodiment 1 will be described with reference to FIG. 3. As shown in FIG. 3, the method of manufacturing electromagnetic wave detector 100 includes a preparation step (S1), an insulating layer formation step (S2), an opening formation step (S3), a two-dimensional material layer formation step (S4), a photosensitizing layer formation step (S5), and an electrode formation step (S6).

First, the preparation step (S1) is performed. In the preparation step (S1), a flat substrate containing silicon (Si) or the like is prepared as first photosensitizing layer 2a.

Subsequently, the insulating layer formation step (S2) is performed. In the insulating layer formation step (S2), first insulating layer 3a is formed on the surface of first photosensitizing layer 2a. First insulating layer 3a may be silicon oxide (SiO₂) formed by thermal oxidation of the surface of first photosensitizing layer 2a, for example, when first photosensitizing layer 2a is silicon (Si). First insulating layer 3a may be formed on the surface of first photosensitizing layer 2a by chemical vapor deposition (CVD) or sputtering. The material of first insulating layer 3a is, for example, a wide-band-gap material such as silicon oxide (SiO₂) (e.g., none-doped silicate glass (NSG), phospho silicate glass (PSG), boro-phospho silicate glass (BPSG)), silicon nitride (SiN), aluminum oxide (Al₂O₃) (e.g., tetraethyl orthosilicate (TEOS) or hafnium oxide (HfO₂)), or a dielectric material such as barium titanate (BaTiO₃), lead zirconate titanate (PbZrTiO₃), strontium bismuth tantalate (SrBi₂Ta₂O₉), bismuth ferrite (BFO:BiFeO₃), lithium niobate (LiNbO₃), or lithium tantalate (LiTaO₃). In order to suppress damage to and contamination of first photosensitizing layer 2a by etching in the opening formation step (S3) described below, a barrier film (not shown) may be formed between first photosensitizing layer 2a and first insulating layer 3a immediately before the insulating layer formation step (S2). The material of the barrier film is a material that is resistant to etching materials. Examples of the material of the barrier film include silicon nitride (SiN), aluminum oxide (Al₂O₃), and graphene.

Subsequently, the opening formation step (S3) is performed. In the opening formation step (S3), an opening is formed in first insulating layer 3a. Specifically, a resist mask is formed on first insulating layer 3a by photolithography, electron beam (EB) lithography, or the like. The resist mask has an opening formed in the region where the opening is to be formed in first insulating layer 3a. Subsequently, first insulating layer 3a is partially removed by wet etching or dry etching, using the resist mask used as a mask, thereby forming the opening. The resist mask is then removed.

Subsequently, the two-dimensional material layer formation step (S4) is performed. In the two-dimensional material layer formation step (S4), two-dimensional material layer 1 is formed so as to cover second electrode portion 4b, first insulating layer 3a, and part or all of first photosensitizing layer 2a which is exposed within the opening of first insulating layer 3a. Two-dimensional material layer 1 is formed by any method. For example, two-dimensional material layer 1 may be formed by epitaxial growth. Alternatively, two-dimensional material layer 1 formed in advance by CVD may be transferred and attached to second electrode portion 4b, first insulating layer 3a, and the part or all of first photosensitizing layer 2a which is exposed within the opening of first insulating layer 3a. Two-dimensional material layer 1 may also be formed by screen printing or the like. Two-dimensional material layer 1 that has peeled off by mechanical peeling or the like may also be transferred to second electrode portion 4b, first insulating layer 3a, and the part or all of first photosensitizing layer 2a which is exposed within the opening of first insulating layer 3a described above. Subsequently, a resist mask is formed on two-dimensional material layer 1 by photolithography or the like. The resist mask is formed so as to cover the region where two-dimensional material layer 1 remains, but is not formed in the region where two-dimensional material layer 1 does not remain. Subsequently, two-dimensional material layer 1 is partially removed by etching with oxygen plasma, using the resist mask as a mask. This removes unwanted portions of two-dimensional material layer 1, thus forming two-dimensional material layer 1 as shown in FIGS. 1 and 2. The resist mask is then removed.

Subsequently, the photosensitizing layer formation step (S5) is performed. In the photosensitizing layer formation step (S5), a protective film (not shown) is formed in the region of two-dimensional material layer 1 where second photosensitizing layer 2b is not formed. The protective film is, for example, a resist. Subsequently, when a semiconductor is used for second photosensitizing layer 2b, second photosensitizing layer 2b is grown on a single-crystal substrate by epitaxial growth using a molecular beam in a high vacuum of 10⁻¹⁰ Torr (133×10⁻¹⁰ Pa) or less. Alternatively, the organic metal compound that is the raw material of second photosensitizing layer 2b is thermally decomposed near the substrate and is grown by epitaxial crystallization.

Further, ionized impurity elements are caused to collide with second photosensitizing layer 2b at high acceleration voltage to penetrate second photosensitizing layer 2b, thereby forming a pn junction, forming a resistance, and adjusting a conductivity. In addition, second photosensitizing layer 2b is peeled off from the single-crystal substrate and is attached by being pressed onto part or some of first photosensitizing layer 2a, first electrode portion 4a, two-dimensional material layer 1, and first insulating layer 3a. Alternatively, the bulk that turns into second photosensitizing layer 2b may be formed as a target material on part or some of first photosensitizing layer 2a, first electrode portion 4a, two-dimensional material layer 1, and first insulating layer 3a by sputtering. When quantum dots are used for second photosensitizing layer 2b, the quantum dots dispersed in a solution are applied onto first photosensitizing layer 2a, first electrode portion 4a, two-dimensional material layer 1, and first insulating layer 3a.

Further, a protective film is formed on a region on the surface of the formed second photosensitizing layer 2b where second photosensitizing layer 2b remains. The protective film is, for example, a resist. Second photosensitizing layer 2b is then etched. Etching may be either wet etching using a chemical solution such as acid or alkali, or dry etching using a reactive species in a plasma. Finally, the resist is removed.

Subsequently, the electrode formation step (S6) is performed. In the electrode formation step (S6), first electrode portion 4a is formed on the surface of first photosensitizing layer 2a. In addition, second electrode portion 4b is formed on the surface of two-dimensional material layer 1.

The method of forming first electrode portion 4a and second electrode portion 4b is, for example, a process as described below. First, a resist mask is formed on the surfaces of first photosensitizing layer 2a, two-dimensional material layer 1, and first insulating layer 3a by photolithography, EB lithography, or the like. The resist mask has openings in the regions where first electrode portion 4a and second electrode portion 4b are to be formed. Subsequently, a film of metal or the like, which turns into first electrode portion 4a and second electrode portion 4b, is formed on the resist mask. Deposition, sputtering, or the like can be used to form this film. At this time, the film is formed so as to extend from inside the openings in the resist mask to the top surface of the resist mask. Subsequently, the resist mask is removed together with part of the film, leaving another part of the film disposed in the openings of the resist mask, and accordingly, first electrode portion 4a and second electrode portion 4b are formed. The method described above is generally referred to as lift-off.

First electrode portion 4a and second electrode portion 4b may be formed by any other method. For example, a film such as a metal film that is to turn into first electrode portion 4a and second electrode portion 4b is formed on the surfaces of first photosensitizing layer 2a, two-dimensional material layer 1, and second photosensitizing layer 2b. Subsequently, a resist mask is formed on the film by photolithography. The resist mask is formed so as to cover the regions where first electrode portion 4a and second electrode portion 4b are formed, but is not formed in the regions other than the regions where first electrode portion 4a and second electrode portion 4b are formed. Subsequently, the film is partially removed by wet etching or dry etching, using the resist mask as a mask. As a result, part of the film remains under the resist mask. This part of the film turns into first electrode portion 4a and second electrode portion 4b. The resist mask is then removed.

Through the steps (S1 to S6) described above, electromagnetic wave detector 100 shown in FIGS. 1 and 2 is obtained.

### <Operating Principle of Electromagnetic Wave Detector 100>

A power supply that applies a voltage V1 is electrically connected between first electrode portion 4a and second electrode portion 4b. A current I flows through two-dimensional material layer 1, which is part of the current path between first electrode portion 4a and second electrode portion 4b. Current I is measured by, for example, an ammeter (not shown). The ammeter is electrically connected between first electrode portion 4a and second electrode portion 4b. A change ΔI in current I in two-dimensional material layer 1 when electromagnetic waves enter electromagnetic wave detector 100 is read as a photocurrent.

The configuration of electromagnetic wave detector 100 is not limited to a configuration in which changes in current in two-dimensional material layer 1 are detected. For example, a constant current may be flowed between first electrode portion 4a and second electrode portion 4b, and changes in voltage (i.e., changes in the voltage value in two-dimensional material layer 1) may be detected.

When electromagnetic waves of the wavelength (detection wavelength) to which first photosensitizing layer 2a is sensitive enter first photosensitizing layer 2a, photocarriers are generated in first photosensitizing layer 2a. In particular, photocarriers are generated in the portion (opening) of first photosensitizing layer 2a which is exposed from two-dimensional material layer 1. The photocarriers are injected into two-dimensional material layer 1. This causes the current flowing through two-dimensional material layer 1 to change. The current that changes due to the injection of photocarriers into two-dimensional material layer 1 is referred to as a photocurrent.

As voltage V1 is applied to first photosensitizing layer 2a, a depletion layer is formed at the interface between first photosensitizing layer 2a and first insulating layer 3a. The polarity of voltage V1 is selected according to the doping type of first photosensitizing layer 2a. When first photosensitizing layer 2a is of p type, voltage V1, which is a positive voltage, is applied to first photosensitizing layer 2a. When first photosensitizing layer 2a is of n type, voltage V1, which is a negative voltage, is applied to first photosensitizing layer 2a.

Photocarriers generated in the depletion layer exert an electric field effect on two-dimensional material layer 1 via first insulating layer 3a. This changes the resistance value of two-dimensional material layer 1, and accordingly, the current value of current I, which is a photocurrent flowing through two-dimensional material layer 1, also changes. In the present embodiment, the change in the electrical characteristics of two-dimensional material layer 1 due to the application of an electric field effect derived from light irradiation to two-dimensional material layer 1 is referred to as a photogating effect.

When electromagnetic waves of the detection wavelength of second photosensitizing layer 2b enter second photosensitizing layer 2b, photocarriers are generated in second photosensitizing layer 2b. The photocarriers generated in the region of second photosensitizing layer 2b where second photosensitizing layer 2b is in contact with two-dimensional material layer 1 are injected into two-dimensional material layer 1. This causes a photocurrent to flow through two-dimensional material layer 1. Thus, a photocurrent can be flowed through two-dimensional material layer 1 by each of first photosensitizing layer 2a and second photosensitizing layer 2b.

When electromagnetic waves of the detection wavelengths of both first photosensitizing layer 2a and second photosensitizing layer 2b enter first photosensitizing layer 2a and second photosensitizing layer 2b, respectively, photocarriers are generated in each of first photosensitizing layer 2a and second photosensitizing layer 2b. When electromagnetic waves of the detection wavelength of one of first photosensitizing layer 2a and second photosensitizing layer 2b enter each of first photosensitizing layer 2a and second photosensitizing layer 2b, photocarriers are generated in the one of first photosensitizing layer 2a and second photosensitizing layer 2b.

An electric field effect is provided to two-dimensional material layer 1 due to the photocarriers generated in the depletion layer formed at the interface between first photosensitizing layer 2a and first insulating layer 3a. Thus, the photogating effect enables amplification of each of the photocarriers generated in first photosensitizing layer 2a and injected into two-dimensional material layer 1 and the photocurrent associated with the photocarriers generated in second photosensitizing layer 2b and injected into two-dimensional material layer 1.

Desirably, since two-dimensional material layer 1 is joined to first photosensitizing layer 2a and second photosensitizing layer 2b by a Schottky junction, no current flows in application of a reverse bias to two-dimensional material layer 1. Thus, when a reverse bias is applied, electromagnetic wave detector 100 can operate in the OFF state.

When a forward bias is applied to two-dimensional material layer 1, current I can be made zero by adjusting voltage V1 and voltage V2. In other words, current I can be made zero during irradiation with no light, and during irradiation with light, only the current derived from the photocarriers injected into two-dimensional material layer 1, which has changed by the photogating effect, can be detected as current I. Thus, when a forward bias is applied, electromagnetic wave detector 100 according to the present embodiment can operate in the OFF state.

The bias currents applied from first electrode portion 4a and second electrode portion 4b may be in the forward direction and the reverse direction, respectively. In this case, a current can be flowed from first photosensitizing layer 2a to two-dimensional material layer 1, and no current can be flowed from second photosensitizing layer 2b to two-dimensional material layer 1. In addition, the bias currents applied from first electrode portion 4a and second electrode portion 4b may be in the reverse direction and the forward direction, respectively. In this case, a current can be flowed from second photosensitizing layer 2b to two-dimensional material layer 1, and no current can be flowed from first photosensitizing layer 2a to two-dimensional material layer 1. In other words, by only changing the bias direction, electromagnetic waves can be detected while spectrally dispersing only the wavelength range to which either first photosensitizing layer 2a or second photosensitizing layer 2b is sensitive.

For example, by applying a forward bias to first photosensitizing layer 2a and applying a reverse bias to second photosensitizing layer 2b, electromagnetic waves of 0.2 μm or more and 1 μm or less, to which only first photosensitizing layer 2a is sensitive, can be selectively detected. In addition, by applying a reverse bias to first photosensitizing layer 2a and applying a forward bias to second photosensitizing layer 2b, electromagnetic waves of 1.1 μm or more and 5.4 μm or less, to which only second photosensitizing layer 2b is sensitive, can be selectively detected.

### <Operation of Electromagnetic Wave Detector 100>

Next, an example operation of electromagnetic wave detector 100 according to Embodiment 1 will be described.

Description will be given of the case where single-layer graphene is used as two-dimensional material layer 1, gold (Au) is used as first electrode portion 4a and second electrode portion 4b, aluminum oxide (AlO) is used as first insulating layer 3a, n-type silicon is used as first photosensitizing layer 2a, and n-type indium antimonide is used as second photosensitizing layer 2b.

When electromagnetic waves of the wavelength of 0.2 μm or more and 1.1 μm or less, to which the n-type silicon of first photosensitizing layer 2a is sensitive, enter first photosensitizing layer 2a, photocarriers are generated in first photosensitizing layer 2a. The photocarriers generated in the portion of first photosensitizing layer 2a which is exposed from two-dimensional material layer 1 are injected into two-dimensional material layer 1.

In addition, a positive voltage is applied to first electrode portion 4a or a negative voltage is applied to second electrode portion 4b so as to be reverse-biased to first photosensitizing layer 2a. As a result, electrons of first photosensitizing layer 2a are attracted to first electrode portion 4a, and holes, which are minority carriers, are attracted to first insulating layer 3a. A depletion layer is formed at the interface between first photosensitizing layer 2a and first insulating layer 3a.

The photocarriers generated in the depletion layer provide an electric field effect to two-dimensional material layer 1 via first insulating layer 3a, thereby producing the photogating effect. Depending on the mobility of the photocarriers of two-dimensional material layer 1, a displacement current is generated in response to the change in electric field. In other words, the photocurrent on two-dimensional material layer 1 associated with the injected photocarriers is amplified by the photogating effect.

When electromagnetic waves of 1 μm or more and 5.4 μm or less, to which the n-type indium antimonide of second photosensitizing layer 2b is sensitive, enter second photosensitizing layer 2b, photocarriers are generated in second photosensitizing layer 2b. The photocarriers generated in second photosensitizing layer 2b are injected into two-dimensional material layer 1. When a positive voltage is applied to second photosensitizing layer 2b, the Fermi level of two-dimensional material layer 1 increases in association with the application of the positive voltage. In this case, the Fermi level of two-dimensional material layer 1 increases due to the photocarriers generated in two-dimensional material layer 1 in association with irradiation with electromagnetic waves. The increase in Fermi level reduces the height of the Schottky barrier formed between the conduction band of second photosensitizing layer 2b and the Fermi level of two-dimensional material layer 1. As a result, photoelectrons are injected from two-dimensional material layer 1 into second photosensitizing layer 2b. In other words, second photosensitizing layer 2b becomes a current source of the photocurrent. This enables detection of electromagnetic waves by second photosensitizing layer 2b.

When electromagnetic waves of 1 μm or more and 1.1 μm or less, which is the detection sensitivity of both first photosensitizing layer 2a and second photosensitizing layer 2b, enter first photosensitizing layer 2a and second photosensitizing layer 2b, photocarriers are generated in both first photosensitizing layer 2a and second photosensitizing layer 2b. The photocarriers generated in both first photosensitizing layer 2a and second photosensitizing layer 2b are injected into two-dimensional material layer 1.

As described above, the photocarriers generated in the depletion layer formed at the interface between first photosensitizing layer 2a and first insulating layer 3a provide an electric field effect to two-dimensional material layer 1. Thus, not only the photocurrent associated with the photocarriers injected from first photosensitizing layer 2a into two-dimensional material layer 1, but also the photocurrent associated with the photocarriers injected from second photosensitizing layer 2b into two-dimensional material layer 1 is greatly amplified by the photogating effect. This can improve the sensitivity of electromagnetic wave detector 100 more than when the photocarriers are detected by first photosensitizing layer 2a or second photosensitizing layer 2b alone.

Desirably, two-dimensional material layer 1 is joined to first photosensitizing layer 2a and second photosensitizing layer 2b by a Schottky junction. Thus, no current flows during application of a reverse bias. Accordingly, electromagnetic wave detector 100 can operate in the OFF state. In addition, during application of a forward bias, a small voltage change causes a large current change in two-dimensional material layer 1. This enables detection of electromagnetic waves.

Next, the functions and effects of the present embodiment will be described.

In the electromagnetic wave detector according to the present embodiment, as shown in FIG. 2, first insulating layer 3a is disposed between two-dimensional material layer 1 and first photosensitizing layer 2a, and the material of two-dimensional material layer 1 is graphene. Thus, the photogating effect can be produced in two-dimensional material layer 1. This can increase the sensitivity of electromagnetic wave detector 100.

More specifically, electromagnetic wave detector 100 includes first photosensitizing layer 2a. Thus, as first photosensitizing layer 2a is irradiated with electromagnetic waves of the detection wavelength of first photosensitizing layer 2a, photocarriers are generated in first photosensitizing layer 2a. The photocarriers generated in first photosensitizing layer 2a are injected into two-dimensional material layer 1, causing a current change. Further, first insulating layer 3a is disposed between first photosensitizing layer 2a and two-dimensional material layer 1, and two-dimensional material layer 1 is graphene. Thus, when a voltage is applied to first photosensitizing layer 2a, a depletion layer is formed at the interface between first photosensitizing layer 2a and first insulating layer 3a. The photocarriers generated in the depletion layer provide an electric field effect to two-dimensional material layer 1 via first insulating layer 3a. As a result, the resistance value changes in two-dimensional material layer 1, and the photogating effect that changes the current flowing through two-dimensional material layer 1 can be generated.

The photogating effect increases the current change due to entrance of the electromagnetic waves, rather than directly increasing the quantum efficiency of the photoelectric conversion material. For this reason, the quantum efficiency calculated from the differential current due to entrance of electromagnetic wave equivalently exceeds 100%. Thus, the amount of change in current I when electromagnetic wave detector 100 according to the present embodiment is irradiated with electromagnetic waves is greater than the amount of current change when the above-mentioned electromagnetic waves enter a conventional electromagnetic wave detector that does not achieve the photogating effect. This can improve the sensitivity of electromagnetic wave detector 100 according to the present embodiment.

The material of two-dimensional material layer 1 is graphene. Thus, the photogating effect of graphene can be achieved. This can improve the sensitivity of electromagnetic wave detector 100.

The material of two-dimensional material layer 1 is graphene. This eliminates the need for using a support substrate in the formation of two-dimensional material layer 1. Thus, the formation of the two-dimensional material layer is not limited to the support substrate. Therefore, the position and shape of two-dimensional material layer 1 can be changed freely in the formation of two-dimensional material layer 1. Specifically, the position and shape of two-dimensional material layer 1 can be changed freely compared with quantum dots formed by spin coating.

When the material of two-dimensional material layer 1 is single-layer graphene, the thickness of two-dimensional material layer 1, which is the thickness of only one atomic layer, is small. In addition, the carrier mobility in single-layer graphene is higher than that of a conventional semiconductor material. Thus, in two-dimensional material layer 1, a large current change is produced in response to a small potential change compared with a conventional semiconductor material. For example, the amount of current change caused by the change in the potential applied to two-dimensional material layer 1 due to the electric field change in first photosensitizing layer 2a and second photosensitizing layer 2b is larger than the amount of current change in a normal semiconductor. Specifically, when calculated based on the electron mobility and thickness of two-dimensional material layer 1, the above amount of current change in two-dimensional material layer 1 is several hundreds to several thousands of times the amount of current change in a normal semiconductor. Therefore, electromagnetic wave detector 100 according to the present embodiment enables high-sensitive electromagnetic wave detection compared with an electromagnetic wave detector that detects only the photocarriers generated in first photosensitizing layer 2a and second photosensitizing layer 2b.

In electromagnetic wave detector 100 according to the present embodiment, in addition to the photocurrents generated in first photosensitizing layer 2a and second photosensitizing layer 2b by light irradiation and the current associated with the photogating effect, a photocurrent also occurs due to the photoelectric conversion effect of two-dimensional material layer 1. Thus, electromagnetic wave detector 100 can detect the original photocurrent caused by the photoelectric conversion effect of two-dimensional material layer 1, in addition to the current associated with the photogating effect.

As shown in FIG. 2, first electrode portion 4a, two-dimensional material layer 1, first photosensitizing layer 2a, and second electrode portion 4b are electrically connected in this order. This allows a signal of electromagnetic wave detector 100 to be read as an electrical signal from between first electrode portion 4a and second electrode portion 4b.

At least one of first photosensitizing layer 2a and second photosensitizing layer 2b may include a semiconductor. In this case, when the semiconductor is irradiated with electromagnetic waves, photocarriers are generated within the semiconductor. Thus, an electric field effect can be produced by the photocarriers. This can improve the sensitivity of electromagnetic wave detector 100.

At least one of first photosensitizing layer 2a and second photosensitizing layer 2b may include an atomic layer material having a band gap. In this case, a Schottky junction is formed between the atomic layer material having a band gap and two-dimensional material layer 1. Thus, as the height of the Schottky barrier is modulated by first electrode portion 4a or second electrode portion 4b, the degree of transport of the photocarriers generated in the photosensitizing layer to two-dimensional material layer 1 can be adjusted.

Two-dimensional material layer 1 may include a turbostratic structure portion. In this case, the carrier mobility in two-dimensional material layer 1 can be improved. This can improve the sensitivity of electromagnetic wave detector 100.

### Embodiment 2

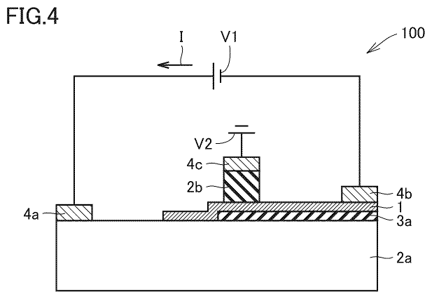

Next, a configuration of electromagnetic wave detector 100 according to Embodiment 2 will be described with reference to FIG. 4. Unless otherwise specified, Embodiment 2 has the same components and the same functions and effects as those of Embodiment 1 described above. Therefore, the same components as those of Embodiment 1 described above have the same reference characters allotted, and description is not repeated.

As shown in FIG. 4, electromagnetic wave detector 100 according to the present embodiment further includes a third electrode portion 4c. Third electrode portion 4c is electrically connected to second photosensitizing layer 2b. Third electrode portion 4c is configured to apply a voltage V2 to second photosensitizing layer 2b. In FIG. 4, third electrode portion 4c is electrically connected to the power conversion device so as to cover the entire top surface of second photosensitizing layer 2b, but third electrode portion 4c only needs to be in contact with part of second photosensitizing layer 2b. For example, third electrode portion 4c may be in contact with the side surface and the bottom surface of second photosensitizing layer 2b. Consequently, electromagnetic wave detector 100 can detect electromagnetic waves even when the electromagnetic waves enter electromagnetic wave detector 100 from any one of the top surface side, the side surface side, and the bottom surface side of third electrode portion 4c.

The material of third electrode portion 4c is a metal, similarly to the materials of first electrode portion 4a and second electrode portion 4b. The material of third electrode portion 4c does not have to be the same as that of first electrode portion 4a or second electrode portion 4b, as long as it is the metal as described above for first electrode portion 4a and second electrode portion 4b.

First photosensitizing layer 2a and second photosensitizing layer 2b are made of different materials. Thus, the height of the Schottky barrier formed by the Schottky junction between first photosensitizing layer 2a and two-dimensional material layer 1 is different from the height of the Schottky barrier formed by the Schottky junction between second photosensitizing layer 2b and two-dimensional material layer 1. The height of the Schottky barrier formed between second photosensitizing layer 2b and two-dimensional material layer 1 may be adjusted through application of a voltage by third electrode portion 4c. In this case, the efficiency of injection of the carriers generated in first photosensitizing layer 2a and second photosensitizing layer 2b by irradiation with electromagnetic waves is improved. This can improve the sensitivity of electromagnetic wave detector 100.

### <Functions and Effects>

Next, the functions and effects of the present embodiment will be described.

In electromagnetic wave detector 100 according to the present embodiment, as shown in FIG. 4, third electrode portion 4c is electrically connected to second photosensitizing layer 2b. Thus, the height of the barrier of the Schottky junction formed between second photosensitizing layer 2b and two-dimensional material layer 1 can be modulated by voltage V2 of third electrode portion 4c. This allows the degree of transport of the photocarriers, generated in second photosensitizing layer 2b, to two-dimensional material layer 1 in association with the irradiation with electromagnetic waves to be adjusted and amplified.

As shown in FIG. 4, electromagnetic wave detector 100 includes third electrode portion 4c. Thus, a clock pulse signal having a frequency characteristic different from that of voltage V1 applied by first electrode portion 4a can be applied as voltage V2 by third electrode portion 4c. A photocurrent ΔI flowing through electromagnetic wave detector 100 is the sum of a first photocurrent ΔI1 associated with the irradiation of first photosensitizing layer 2a with electromagnetic waves and a second photocurrent ΔI2 associated with the irradiation of second photosensitizing layer 2b with electromagnetic waves. As a waveform having a frequency characteristic different from that of voltage V1 applied to first photosensitizing layer 2a is applied to second photosensitizing layer 2b as voltage V2, a current change ΔI2clock derived from the frequency change in voltage V2 is generated in ΔI. This allows the current change in ΔI2 to be read based on ΔI2clock. Consequently, a signal value of ΔI1 and a signal value of ΔI2 in a current I component are obtained separately, and thus, the amount of light of the electromagnetic waves that have entered first photosensitizing layer 2a and the amount of light of the electromagnetic waves that have entered second photosensitizing layer 2b are obtained separately. This enables spectral detection of electromagnetic wave detector 100 having a plurality of wavelengths by a single electromagnetic wave detector 100.

In detection of the current change in differential current ΔI2, a reference signal of voltage V2 may also be obtained. In this case, differential current ΔI2 may be detected by lock-in detection through comparison with a measured signal. Compared with the case where differential current ΔI2 is detected without lock-in detection, the amount of light of electromagnetic waves that have entered second photosensitizing layer 2b can be detected with higher accuracy.

The materials of first photosensitizing layer 2a and second photosensitizing layer 2b may be materials having a band gap. In this case, two-dimensional material layer 1 forms a Schottky junction with first photosensitizing layer 2a and second photosensitizing layer 2b. Thus, no current flows through two-dimensional material layer 1 during application of a reverse bias, and accordingly, electromagnetic wave detector 100 can operate in the OFF state during application of a reverse bias. In contrast, during application of a forward bias, current I flowing through two-dimensional material layer 1 can be made zero by adjusting voltage V1 applied by first electrode portion 4a and voltage V2 applied by second electrode portion 4b. In other words, current I flowing through two-dimensional material layer 1 can be made zero during irradiation with no light, and during light irradiation, only the current derived from the photocarriers injected into two-dimensional material layer 1, which has changed due to the photogating effect, can be detected as current I. Thus, electromagnetic wave detector 100 according to the present embodiment can operate in the OFF state during application of a forward bias.

As shown in FIG. 4, electromagnetic wave detector 100 further includes third electrode portion 4c. Thus, voltage V1 and voltage V2 can be separately applied to first photosensitizing layer 2a and second photosensitizing layer 2b by first electrode portion 4a and the third electrode portion 4c, respectively. By reversing the bias directions of voltage V1 and voltage V2, the photocurrent of either first photosensitizing layer 2a or second photosensitizing layer 2b alone can be obtained. For example, when a reverse bias is applied to first photosensitizing layer 2a and a forward bias is applied to second photosensitizing layer 2b, no current flows between first photosensitizing layer 2a and two-dimensional material layer 1, and a current flows between second photosensitizing layer 2b and two-dimensional material layer 1. Thus, electromagnetic wave detector 100 can operate in the OFF state for the detection wavelength of first photosensitizing layer 2a and can respond to the detection wavelength of second photosensitizing layer 2b. This allows electromagnetic wave detector 100 to perform the spectral operation.

### Embodiment 3

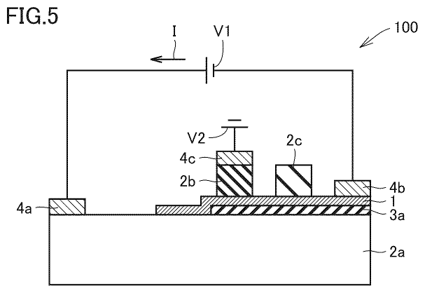

Next, a configuration of electromagnetic wave detector 100 according to Embodiment 3 will be described with reference to FIG. 5. Unless otherwise specified, Embodiment 3 has the same components and the same functions and effects as those of Embodiment 2 described above. Therefore, the same components as those of Embodiment 2 described above have the same reference characters allotted, and description is not repeated.

As shown in FIG. 5, electromagnetic wave detector 100 according to the present embodiment further includes a third photosensitizing layer 2c. Third photosensitizing layer 2c is connected to two-dimensional material layer 1. In the present embodiment, third photosensitizing layer 2c is electrically connected to two-dimensional material layer 1. Third photosensitizing layer 2c has an absorption maximum value in an electromagnetic wavelength range different from those of first photosensitizing layer 2a and second photosensitizing layer 2b. Third photosensitizing layer 2c can cause a voltage change in the wavelength range different from those of first photosensitizing layer 2a and second photosensitizing layer 2b.

Desirably, third photosensitizing layer 2c includes a semiconductor. Also, desirably, third photosensitizing layer 2c includes an atomic layer material having a band gap. In this case, a Schottky junction is formed between third photosensitizing layer 2c and two-dimensional material layer 1.

The material of third photosensitizing layer 2c may be one or a combination of materials such as germanium (Ge), a compound semiconductor (e.g., a group III-V semiconductor or a group II-V semiconductor), mercury cadmium telluride (HgCdTe), indium antimonide (InSb), lead selenide (PbSe), lead sulfide (PbS), cadmium sulfide (CdS), gallium nitride (GaN), silicon carbide (SiC), gallium phosphide (GaP), indium gallium arsenide (InGaAs), or indium arsenide (InAs). The material of third photosensitizing layer 2c may be one or a combination of a substrate containing quantum wells or quantum dots, and a material such as a Type II superlattice.

The material of third photosensitizing layer 2c may be a quantum dot. Specifically, the material of third photosensitizing layer 2c may be a molybdenum disulfide (MoS₂) quantum dot, a tungsten disulfide (WS₂) quantum dot, a core-shell structured quantum dot of indium phosphide (InP) and zinc sulfide (ZnS), a core quantum dot of cadmium telluride (CdTe), a carbon quantum dot, a graphene quantum dot, a core-shell structured quantum dot of cadmium selenide (CdSe) and cadmium sulfide (CdS), a core-shell structured quantum dot of cadmium selenide (CdSe) and zinc sulfide (ZnS), a core-shell structured quantum dot of cadmium sulfide (CdS) and zinc sulfide (ZnS), a perovskite (APbX3 [A=Cs, MA (methylammonium), FA (formamidinium), X=Cl, Br, I)] quantum dot, a lead sulfide (PbS) quantum dot, or a core quantum dot of lead sulfide (PbS).

Desirably, the thickness of third photosensitizing layer 2c is 10 μm or less. As the thickness of third photosensitizing layer 2c becomes smaller, the amount of deactivation of the photocarriers generated in third photosensitizing layer 2c in association with irradiation with electromagnetic waves and transported to two-dimensional material layer 1 decreases in third photosensitizing layer 2c. This can improve the sensitivity of electromagnetic wave detector 100.

### <Operating Principle>

When electromagnetic waves of the detection wavelength of third photosensitizing layer 2c enter third photosensitizing layer 2c, photocarriers are generated within third photosensitizing layer 2c. The photocarriers generated in the region of third photosensitizing layer 2c which is in contact with two-dimensional material layer 1 are injected into two-dimensional material layer 1. This generates a photocurrent in two-dimensional material layer 1.

### <Functions and Effects>

Next, the functions and effects of the present embodiment will be described.

According to the present embodiment, as shown in FIG. 5, electromagnetic wave detector 100 further includes third photosensitizing layer 2c. When electromagnetic waves of the detection wavelengths of both second photosensitizing layer 2b and third photosensitizing layer 2c enter second photosensitizing layer 2b and third photosensitizing layer 2c, photocarriers are generated in both second photosensitizing layer 2b and third photosensitizing layer 2c. The photocarriers are injected into two-dimensional material layer 1. The photocarriers generated in the depletion layer formed at the interface between first photosensitizing layer 2a and first insulating layer 3a produce the photogating effect in two-dimensional material layer 1. The photogating effect also amplifies the photocurrent on two-dimensional material layer 1 associated with the photocarriers generated by third photosensitizing layer 2c and injected into two-dimensional material layer 1. Therefore, the sensitivity of electromagnetic wave detector 100 can be improved more than when the photocarriers generated by any one of first photosensitizing layer 2a, second photosensitizing layer 2b, and third photosensitizing layer 2c are detected.

The amount of change in current I when electromagnetic wave detector 100 according to the present embodiment is irradiated with electromagnetic waves includes the amount of the photocurrent generated by the photoelectric conversion in two-dimensional material layer 1, in addition to the amount of change in the current generated by the resistance change of two-dimensional material layer 1 associated with the photocarriers generated in first photosensitizing layer 2a, the amount of change in the current generated by the resistance change of two-dimensional material layer 1 associated with the photocarriers generated in second photosensitizing layer 2b, and the amount of change in the current generated by the resistance change of two-dimensional material layer 1 associated with the photocarriers generated in third photosensitizing layer 2c. In other words, in electromagnetic wave detector 100 according to the present embodiment, in addition to the current generated by the above-mentioned photogating effect due to the entrance of electromagnetic waves, the original photocurrent resulting from the photoelectric conversion efficiency of two-dimensional material layer 1 can also be detected. This enables high-sensitivity electromagnetic wave detection compared with a conventional electromagnetic wave detector that detects the photocarriers generated by at least one of first photosensitizing layer 2a, second photosensitizing layer 2b, and third photosensitizing layer 2c.

Electromagnetic wave detector 100 includes third photosensitizing layer 2c. Thus, as first photosensitizing layer 2a is irradiated with electromagnetic waves of the detection wavelength of first photosensitizing layer 2a, photocarriers are generated in first photosensitizing layer 2a. The photocarriers generated in first photosensitizing layer 2a are injected into two-dimensional material layer 1, causing a current change. First insulating layer 3a is disposed between first photosensitizing layer 2a and two-dimensional material layer 1. Thus, as a voltage is applied to first photosensitizing layer 2a, a depletion layer is formed at the interface between first photosensitizing layer 2a and first insulating layer 3a. The photocarriers generated in the depletion layer provide an electric field effect to two-dimensional material layer 1 via first insulating layer 3a. As a result, the resistance value changes in two-dimensional material layer 1, and the photogating effect that changes the current flowing through two-dimensional material layer 1 can be produced.

When electromagnetic wave detector 100 according to the present embodiment is irradiated with electromagnetic waves from the back surface, the electromagnetic waves pass through first photosensitizing layer 2a and enter second photosensitizing layer 2b and third photosensitizing layer 2c. Electromagnetic waves of the wavelength range that does not allow the electromagnetic waves to pass through first photosensitizing layer 2a do not enter second photosensitizing layer 2b or third photosensitizing layer 2c. Thus, even when electromagnetic waves of the respective wavelengths to which second photosensitizing layer 2b and third photosensitizing layer 2c are not sensitive (which allow electromagnetic waves to pass through second photosensitizing layer 2b and third photosensitizing layer 2c, respectively) enter second photosensitizing layer 2b and third photosensitizing layer 2c, the influence of stray light can be reduced.

By selecting the bias directions of application from first electrode portion 4a, second electrode portion 4b, and third electrode portion 4c from among the forward direction and the reverse direction, the currents from first photosensitizing layer 2a, second photosensitizing layer 2b, and third photosensitizing layer 2c to the atomic layer material can be controlled. Thus, by controlling the bias direction, electromagnetic waves can be detected while selectively performing spectral dispersion of only the respective wavelength ranges to which first photosensitizing layer 2a, second photosensitizing layer 2b, and third photosensitizing layer 2c are sensitive.

Third photosensitizing layer 2c may include a semiconductor. In this case, when the semiconductor is irradiated with electromagnetic waves, photocarriers are generated within the semiconductor. Thus, an electric field effect can be produced by the photocarriers. This can improve the sensitivity of electromagnetic wave detector 100.

Third photosensitizing layer 2c may include an atomic layer material having a band gap. In this case, a Schottky junction is formed between the atomic layer material having a band gap and two-dimensional material layer 1. Thus, as the height of the Schottky barrier is modulated, the degree of transport of the photocarriers generated in the photosensitizing layer to two-dimensional material layer 1 can be adjusted.

### Embodiment 4

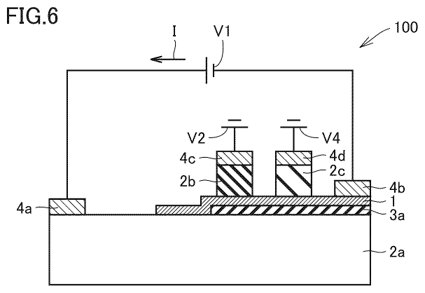

Next, a configuration of electromagnetic wave detector 100 according to Embodiment 4 will be described with reference to FIG. 6. Unless otherwise specified, Embodiment 4 has the same components and the same functions and effects as those of Embodiment 3 described above. Therefore, the same components as those of Embodiment 3 described above have the same reference characters allotted, and description is not repeated.

As shown in FIG. 6, electromagnetic wave detector 100 according to the present embodiment further includes a fourth electrode portion 4d. Fourth electrode portion 4d is electrically connected to third photosensitizing layer 2c. Fourth electrode portion 4d is configured to apply a voltage V4 to third photosensitizing layer 2c. Fourth electrode portion 4d is connected to the top surface of third photosensitizing layer 2c. Fourth electrode portion 4d may also be connected to the side surface or the bottom surface of third electrode portion 4c. Electromagnetic wave detector 100 is configured to apply voltage V4 to third photosensitizing layer 2c by fourth electrode portion 4d.

### <Functions and Effects>

Next, the functions and effects of the present embodiment will be described.

In electromagnetic wave detector 100 according to the present embodiment, as shown in FIG. 6, fourth electrode portion 4d is electrically connected to third photosensitizing layer 2c. Thus, the height of the barrier of a Schottky junction formed between third photosensitizing layer 2c and two-dimensional material layer 1 can be modulated by voltage V4 of fourth electrode portion 4d. This allows the degree of transport of the photocarriers, generated in third photosensitizing layer 2c, to two-dimensional material layer 1 in association with the irradiation with electromagnetic waves to be adjusted and amplified.

Electromagnetic wave detector 100 includes fourth electrode portion 4d. Thus, a clock pulse signal having a frequency characteristic different from those of voltage V1 applied by first electrode portion 4a and voltage V2 applied by third electrode portion 4c can be applied as voltage V4 by fourth electrode portion 4d. Photocurrent ΔI flowing through electromagnetic wave detector 100 is the sum of first photocurrent ΔI1 associated with irradiation of first photosensitizing layer 2a with electromagnetic waves, second photocurrent ΔI2 associated with irradiation of second photosensitizing layer 2b with electromagnetic waves, and a third photocurrent ΔI3 associated with irradiation of third photosensitizing layer 2c with electromagnetic waves. A waveform having a frequency characteristic different from those of voltage V1 applied to first photosensitizing layer 2a and voltage V2 applied to second photosensitizing layer 2b is applied to third photosensitizing layer 2c as voltage V4, and accordingly, a current change ΔI3clock derived from the frequency change in voltage V4 occurs in ΔI. This allows the current change in ΔI3 to be read based on ΔI3clock. From the above, the signal value of ΔI1, the signal value of ΔI2, and the signal value of ΔI3 in current I component are obtained separately. Thus, the amount of light of the electromagnetic waves that have entered first photosensitizing layer 2a, the amount of light of the electromagnetic waves that have entered second photosensitizing layer 2b, and the amount of light of the electromagnetic waves that have entered third photosensitizing layer 2c are obtained separately. This enables spectral detection of electromagnetic wave detector 100 having a plurality of wavelengths by a single electromagnetic wave detector 100.

In detection of the current change in differential current ΔI3, a reference signal of voltage V2 may also be obtained. In this case, differential current ΔI3 may be detected by lock-in detection through comparison with a measured signal. Compared with the case where differential current ΔI3 is detected without lock-in detection, the amount of light of the electromagnetic waves that have entered third photosensitizing layer 2c can be detected with higher accuracy.

Electromagnetic wave detector 100 further includes fourth electrode portion 4d. Thus, voltage V1, voltage V2, and voltage V4 can be separately applied to first photosensitizing layer 2a, second photosensitizing layer 2b, and third photosensitizing layer 2c by first electrode portion 4a, third electrode portion 4c, and fourth electrode portion 4d, respectively. By reversing the bias directions of voltage V1, voltage V2, and voltage V4, thus, the photocurrent of any one of first photosensitizing layer 2a, second photosensitizing layer 2b, and third photosensitizing layer 2c can be obtained. For example, when a reverse bias is applied to first photosensitizing layer 2a and second photosensitizing layer 2b and a forward bias is applied to third photosensitizing layer 2c, no current flows between first photosensitizing layer 2a and two-dimensional material layer 1 and between second photosensitizing layer 2b and two-dimensional material layer 1, and a current flows between third photosensitizing layer 2c and two-dimensional material layer 1. Thus, electromagnetic wave detector 100 can operate in the OFF state for the detection wavelengths of first photosensitizing layer 2a and second photosensitizing layer 2b, and can respond to the detection wavelength of third photosensitizing layer 2c. This allows electromagnetic wave detector 100 to perform the spectral operation.

First photosensitizing layer 2a, second photosensitizing layer 2b, and third photosensitizing layer 2c may include an atomic layer material having a band gap. In this case, two-dimensional material layer 1 forms a Schottky junction with first photosensitizing layer 2a, second photosensitizing layer 2b, and third photosensitizing layer 2c. Thus, no current flows through two-dimensional material layer 1 during application of a reverse bias, and accordingly, electromagnetic wave detector 100 can operate in the OFF state. In contrast, during application of a forward bias, current I flowing through two-dimensional material layer 1 can be made zero by adjusting voltage V1 applied by first electrode portion 4a, voltage V2 applied by second electrode portion 4b, and voltage V4 applied by third electrode portion 4c. In other words, current I flowing through two-dimensional material layer 1 can be made zero during irradiation with no light, and during light irradiation, only the current derived from the photocarriers injected into two-dimensional material layer 1, which has changed by the photogating effect, can be detected as current I. Thus, electromagnetic wave detector 100 according to the present embodiment can operate in the OFF state also during application of a forward bias.

### Embodiment 5

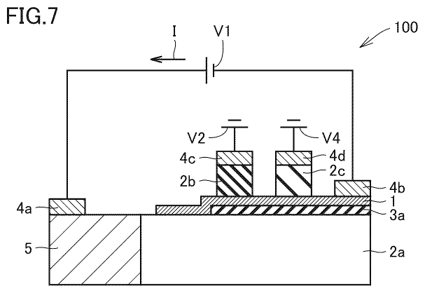

Next, a configuration of electromagnetic wave detector 100 according to Embodiment 5 will be described with reference to FIG. 7. Unless otherwise specified, Embodiment 5 has the same components and the same functions and effects as those of Embodiment 4 described above. Therefore, the same components as those of Embodiment 4 described above have the same reference characters allotted, and description is not repeated.

As shown in FIG. 7, electromagnetic wave detector 100 according to the present embodiment further includes a signal processing circuit 5. Signal processing circuit 5 is disposed between first photosensitizing layer 2a and first insulating layer 3a. Signal processing circuit 5 is configured to read an electrical signal between first electrode portion 4a and second electrode portion 4b. The material of first electrode portion 4a according to the present embodiment is silicon (Si).

Signal processing circuit 5 is configured as a readout circuit. Signal processing circuit 5 is an integrated circuit. The readout format is, for example, a capacitive trans-impedance amplifier (CTIA) type or a direct injection (DI) type. The readout format may be any other format.

Desirably, signal processing circuit 5 is made of the same material as that of first photosensitizing layer 2a, but the present disclosure is not limited thereto. Signal processing circuit 5 may be provided on, for example, the surface of first photosensitizing layer 2a. Signal processing circuit 5 provided on the surface of first photosensitizing layer 2a may be electrically connected to first electrode portion 4a provided on the surface of first photosensitizing layer 2a. Signal processing circuit 5 may be provided on, for example, the back surface of first photosensitizing layer 2a. Signal processing circuit 5 provided on the back surface of first photosensitizing layer 2a may be electrically connected to first electrode portion 4a provided on the back surface of first photosensitizing layer 2a.

Although not shown, signal processing circuit 5 may be electrically connected to first electrode portion 4a by aluminum (Al), aluminum (Al) doped with silicon (Si) (silicon-doped aluminum), or gold (Au) wire bonding. It is generally difficult to form signal processing circuit 5 by forming elements such as complementary MOS (CMOS) and resistors in a compound semiconductor other than silicon. In addition, it is not practical to form the above-mentioned elements within the light-sensitive material such as first photosensitizing layer 2a, because this would lead to a decrease in the performance of electromagnetic wave detector 100, which is caused by a malfunction, a cost increase, a reduced production yield, or a reduced light-receiving area.

As described above, the formation of the readout circuit and first electrode portion 4a on the same silicon as that of first photosensitizing layer 2a is referred to as monolithic formation. Signal processing circuit 5 obtained by monolithic formation is generally used in visible light sensors or uncooled infrared sensors. In monolithic formation, first photosensitizing layer 2a and signal processing circuit 5 are formed in the silicon substrate, leading to a reduced manufacturing cost and an increased production yield.

### <Functions and Effects>

Next, the functions and effects of the present embodiment will be described.

According to the present embodiment, as shown in FIG. 7, electromagnetic wave detector 100 further includes signal processing circuit 5. This enables accumulation, multiplication, and output to the external circuit, the photocurrent generated in two-dimensional material layer 1 by the photocarriers generated in first photosensitizing layer 2a, second photosensitizing layer 2b, and third photosensitizing layer 2c using signal processing circuit 5.

### Embodiment 6

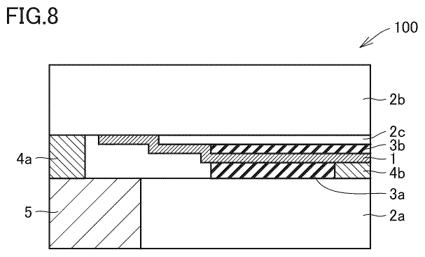

Next, a configuration of electromagnetic wave detector 100 according to Embodiment 6 will be described with reference to FIG. 8. Unless otherwise specified, Embodiment 6 has the same components and the same functions and effects as those of Embodiment 5 described above. Therefore, the same components as those of Embodiment 5 described above have the same reference characters allotted, and description is not repeated.

As shown in FIG. 8, in electromagnetic wave detector 100 according to the present embodiment, first electrode portion 4a is connected to signal processing circuit 5. First photosensitizing layer 2a is electrically connected to signal processing circuit 5. First insulating layer 3a and second electrode portion 4b are provided on first photosensitizing layer 2a. Two-dimensional material layer 1 extends from the top surface of second electrode portion 4b to the top surface of first insulating layer 3a, the bottom surface of second insulating layer 3b, the bottom surface of third photosensitizing layer 2c, and the bottom surface of second photosensitizing layer 2b. Third insulating layer 3c is provided on the top surface of two-dimensional material layer 1. Third photosensitizing layer 2c is provided on the bottom surface of second photosensitizing layer 2b, the top surface of two-dimensional material layer 1, and the top surface of second insulating layer 3b. Second photosensitizing layer 2b is provided on the top surface of first electrode portion 4a, the front surface of two-dimensional material layer 1, and the top surface of third photosensitizing layer 2c. Second insulating layer 3b is provided on the top surface of two-dimensional material layer 1.

Two-dimensional material layer 1 includes a first portion, a second portion, a third portion, and a fourth portion. The first portion is connected to first insulating layer 3a and second insulating layer 3b. The first portion is in contact with the top surface of first insulating layer 3a and the bottom surface of second insulating layer 3b. The second portion is electrically connected to third photosensitizing layer 2c. The second portion is in contact with the bottom surface of third photosensitizing layer 2c. Desirably, the second portion is joined to third photosensitizing layer 2c by a Schottky junction. The third portion is electrically connected to second photosensitizing layer 2b. Desirably, the third portion is joined to second photosensitizing layer 2b by a Schottky junction. The fourth portion is electrically connected to second electrode portion 4b. The fourth portion is disposed so as to be connected to the bottom surface of first insulating layer 3a and the top surface of second electrode portion 4b.

The first portion to the fourth portion may have an equal thickness. The surface of two-dimensional material layer 1 may have unevenness caused by each of the first to fourth portions. The distance between the top surface of the third portion and the bottom surface of second photosensitizing layer 2b is less than the distance between the top surface of the first portion, the second portion, the fourth portion and the bottom surface of first photosensitizing layer 2a. The distance between the top surface of the second portion and the bottom surface of third photosensitizing layer 2c is less than the distance between the top surface of the first portion, the fourth portion and the bottom surface of third photosensitizing layer 2c.

In FIG. 8, the first portion is disposed so as to be in contact with first insulating layer 3a and second insulating layer 3b in all regions, but the first portion may also include a region that is in contact with only any one of first insulating layer 3a and second insulating layer 3b. When the region of the first portion which is in contact with first insulating layer 3a and second insulating layer 3b is small, the amount of light of electromagnetic waves that are absorbed by passing through first insulating layer 3a and second insulating layer 3b at the entrance of electromagnetic waves decreases, leading to improved sensitivity of electromagnetic wave detector 100.

A protective film (not shown) may be formed on the surface of the second portion and the surface of the third portion of two-dimensional material layer 1. The protective film may be provided so as to cover the surroundings of two-dimensional material layer 1, first insulating layer 3a, second photosensitizing layer 2b, second electrode portion 4b, and third electrode portion 4c on first photosensitizing layer 2a. The material of the protective film may be any material, and for example, is an insulating layer containing silicon oxide (SiO₂). The material of the protective film is an insulator such as an oxide or a nitride. Examples of the material of the protective film include silicon oxide (SiO₂), silicon nitride (SiN), hafnium oxide (HfO₂), aluminum oxide (Al₂O₃), and boron nitride (BN).

First electrode portion 4a electrically connects signal processing circuit 5 to second photosensitizing layer 2b. Second electrode portion 4b electrically connects first photosensitizing layer 2a to two-dimensional material layer 1.

First electrode portion 4a and second electrode portion 4b may include a metal bump (not shown) that electrically connects first photosensitizing layer 2a to two-dimensional material layer 1. The material of the metal bump is, for example, an electrically conductive material, such as gold (Au) or indium (In). The connection between first photosensitizing layer 2a and two-dimensional material layer 1 using the metal bump is referred to as flip-chip mounting or hybrid bonding. Flip-chip mounting or hybrid bonding is commonly used in quantum-type infrared sensors. Compared with the case where wire bonding or metal wiring is used, flip-chip mounting or hybrid bonding can reduce the mounting area and shorten the wiring. Thus, the power supply noise or losses derived from the inductance resistance of the wiring can be reduced by flip-chip mounting or hybrid bonding. Therefore, good electrical characteristics are obtained.

An electrode pad (not shown) may be provided between the metal bump and first electrode portion 4a or between the metal bump and two-dimensional material layer 1. The material of the electrode pad is, for example, an electrically conductive material such as an aluminum-silicon (Al—Si)-based alloy, nickel (Ni), or gold (Au).

A voltage (not shown) is applied between first electrode portion 4a and first photosensitizing layer 2a via signal processing circuit 5. The current change during irradiation with electromagnetic waves is measured as the amount of electromagnetic waves detected. In addition to the current change, the voltage change when electromagnetic wave detector 100 is driven by a constant current may also be detected as the amount of electromagnetic waves detected.

### <Functions and Effects>

Next, the functions and effects of the present embodiment will be described.

In electromagnetic wave detector 100 according to the present embodiment, as shown in FIG. 8, the first electromagnetic wave detector portion including third photosensitizing layer 2c, second insulating layer 3b, and two-dimensional material layer 1 on second photosensitizing layer 2b and the second electromagnetic wave detector portion including first photosensitizing layer 2a, signal processing circuit 5, first insulating layer 3a, first electrode portion 4a, and second electrode portion 4b can be separately produced in advance. The first electromagnetic wave detector portion and the second electromagnetic wave detector portion can be integrated by flip-chip bonding to produce electromagnetic wave detector 100. In the production, the lithography process for forming a photosensitizing layer and an electrode on two-dimensional material layer 1 can be omitted. In addition, two-dimensional material layer 1 is protected by first photosensitizing layer 2a and second photosensitizing layer 2b. Thus, defects and failures of two-dimensional material layer 1 in the manufacturing process can be suppressed to improve a production yield.

### Embodiment 7

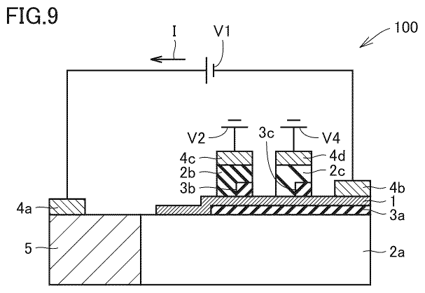

Next, a configuration of electromagnetic wave detector 100 according to Embodiment 7 will be described with reference to FIG. 9. Unless otherwise specified, Embodiment 7 has the same components and the same functions and effects as those of Embodiment 5 described above. Therefore, the same components as those of Embodiment 5 described above have the same reference characters allotted, and description is not repeated.

As shown in FIG. 9, electromagnetic wave detector 100 according to the present embodiment further includes a second insulating layer 3b. Second insulating layer 3b is disposed between second photosensitizing layer 2b and two-dimensional material layer 1. Second insulating layer 3b is provided to be connected to two-dimensional material layer 1 and second photosensitizing layer 2b. Second photosensitizing layer 2b includes a portion directly connected to two-dimensional material layer 1 and a portion connected to two-dimensional material layer 1 with second insulating layer 3b in between.

Electromagnetic wave detector 100 further includes a third insulating layer 3c. Third insulating layer 3c is disposed between third photosensitizing layer 2c and two-dimensional material layer 1. Third insulating layer 3c is disposed to be connected to two-dimensional material layer 1 and third photosensitizing layer 2c. Third photosensitizing layer 2c includes a portion directly connected to two-dimensional material layer 1 and a portion connected to two-dimensional material layer 1 with third insulating layer 3c in between.

The materials of second insulating layer 3b and third insulating layer 3c are, for example, silicon oxide (SiO₂). The materials of second insulating layer 3b and third insulating layer 3c are not limited to silicon oxide, and may be, for example, tetraethyl orthosilicate (Si(OC₂H₅)₄), silicon nitride (Si₃N₄), hafnium oxide (HfO₂), aluminum oxide (Al₂O₃), nickel oxide (NiO), boron nitride (BN), or a siloxane-based polymer material. For example, the atomic arrangement of boron nitride (BN) is similar to the atomic arrangement of graphene. Thus, when boron nitride (BN) comes into contact with two-dimensional material layer 1 made of graphene, a decrease in the electron mobility of two-dimensional material layer 1 is suppressed. Therefore, boron nitride (BN) is suitable for second insulating layer 3b and third insulating layer 3c, which are the base films disposed under two-dimensional material layer 1.

The thickness of second insulating layer 3b and the thickness of third insulating layer 3c are not particularly limited as long as the region of two-dimensional material layer 1 which is located under second insulating layer 3b is isolated from the region of second photosensitizing layer 2b which is located above second insulating layer 3b, the region of two-dimensional material layer 1 which is located below third insulating layer 3c is isolated from the region of third photosensitizing layer 2c which is located above third insulating layer 3c, and no tunnel current is generated. Smaller thicknesses of second insulating layer 3b and third insulating layer 3c lead to a greater degree of change in the electric field of two-dimensional material layer 1 caused by the photocarriers generated at the interface between second insulating layer 3b and second photosensitizing layer 2b and the photocarriers generated at the interface between third insulating layer 3c and third photosensitizing layer 2c. Thus, it is desirable that the thicknesses of second insulating layer 3b and third insulating layer 3c be as thin as possible.

Regarding electromagnetic wave detector 100 according to the present embodiment, a configuration having both second insulating layer 3b and third insulating layer 3c has been described, but similar effects are obtained also by a configuration including only second insulating layer 3b or only third insulating layer 3c. In other words, the photogating effect and higher sensitivity derived from the depletion layer formed between second photosensitizing layer 2b and second insulating layer 3b, or the photogating effect and higher sensitivity derived from the depletion layer formed between third photosensitizing layer 2c and third insulating layer 3c are obtained.

### <Functions and Effects>

Next, the functions and effects of the present embodiment will be described.

According to the present embodiment, as shown in FIG. 9, electromagnetic wave detector 100 includes second photosensitizing layer 2b. Thus, as second photosensitizing layer 2b is irradiated with electromagnetic waves of the detection wavelength of second photosensitizing layer 2b, photocarriers are generated in second photosensitizing layer 2b. The photocarriers generated in second photosensitizing layer 2b are injected into two-dimensional material layer 1, causing a current change. Second insulating layer 3b is disposed between second photosensitizing layer 2b and two-dimensional material layer 1. Thus, as a voltage is applied to second photosensitizing layer 2b, a depletion layer is formed at the interface between second photosensitizing layer 2b and second insulating layer 3b. The photocarriers generated in the depletion layer exert an electric field effect on two-dimensional material layer 1 via second insulating layer 3b. As a result, a photogating effect can be produced that changes the current flowing through two-dimensional material layer 1 by changing the resistance value in two-dimensional material layer 1. This can improve the sensitivity of electromagnetic wave detector 100.

As shown in FIG. 9, electromagnetic wave detector 100 includes third photosensitizing layer 2c. Thus, as third photosensitizing layer 2c is irradiated with electromagnetic waves of the detection wavelength of third photosensitizing layer 2c, photocarriers are generated in third photosensitizing layer 2c. The photocarriers generated in third photosensitizing layer 2c are injected into two-dimensional material layer 1, causing a current change. Third insulating layer 3c is disposed between third photosensitizing layer 2c and two-dimensional material layer 1. Thus, when a voltage is applied to third photosensitizing layer 2c, a depletion layer is formed at the interface between third photosensitizing layer 2c and third insulating layer 3c. The photocarriers generated in the depletion layer exert an electric field effect on two-dimensional material layer 1 via third insulating layer 3c. As a result, a photogating effect can be produced that changes the current flowing through two-dimensional material layer 1 by changing the resistance value in two-dimensional material layer 1. This can improve the sensitivity of electromagnetic wave detector 100.

The amount of change in current I when electromagnetic wave detector 100 according to the present embodiment is irradiated with electromagnetic waves includes the amount of the photocurrent generated by the photoelectric conversion in two-dimensional material layer 1, in addition to the amount of change in the current generated by the resistance change of two-dimensional material layer 1 associated with the photocarriers generated in first photosensitizing layer 2a, the amount of change in the current generated by the resistance change of two-dimensional material layer 1 associated with the photocarriers generated in second photosensitizing layer 2b, and the amount of change in the current generated by the resistance change of two-dimensional material layer 1 associated with the photocarriers generated in third photosensitizing layer 2c. In other words, in electromagnetic wave detector 100 according to the present embodiment, the original photocurrent resulting from the photoelectric conversion efficiency of two-dimensional material layer 1 is also detected by the entrance of electromagnetic waves, in addition to the current generated by the above-mentioned photogating effect. This enables high-sensitivity electromagnetic wave detection, compared with a conventional electromagnetic wave detector that detects photocarriers generated in first photosensitizing layer 2a, second photosensitizing layer 2b, or third photosensitizing layer 2c alone.

### Embodiment 8

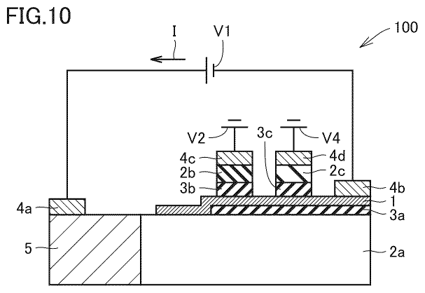

Next, a configuration of electromagnetic wave detector 100 according to Embodiment 8 will be described with reference to FIG. 10. Unless otherwise specified, Embodiment 8 has the same components and the same functions and effects as those of Embodiment 7 described above. Therefore, the same components as those of Embodiment 7 described above have the same reference characters allotted, and description is not repeated.

As shown in FIG. 10, in electromagnetic wave detector 100 according to the present embodiment, second photosensitizing layer 2b is entirely covered with second insulating layer 3b. Thus, two-dimensional material layer 1 is connected to second photosensitizing layer 2b with second insulating layer 3b in between. Two-dimensional material layer 1 is not electrically connected to second photosensitizing layer 2b.

Third photosensitizing layer 2c is entirely covered with third insulating layer 3c. Thus, two-dimensional material layer 1 is connected to third photosensitizing layer 2c with third insulating layer 3c in between. Two-dimensional material layer 1 is not electrically connected to second photosensitizing layer 2b.

### <Functions and Effects>

Next, the functions and effects of the present embodiment will be described.

In electromagnetic wave detector 100 according to the present embodiment, as shown in FIG. 10, second photosensitizing layer 2b is entirely covered with second insulating layer 3b. Thus, only the electric field effect can be selectively produced in two-dimensional material layer 1 without sending the photocarriers generated in second photosensitizing layer 2b to two-dimensional material layer 1.

As shown in FIG. 10, third photosensitizing layer 2c is entirely covered with third insulating layer 3c. Therefore, only the electric field effect can be selectively produced in two-dimensional material layer 1 without sending the photocarriers generated in third photosensitizing layer 2c to two-dimensional material layer 1.

### Embodiment 9

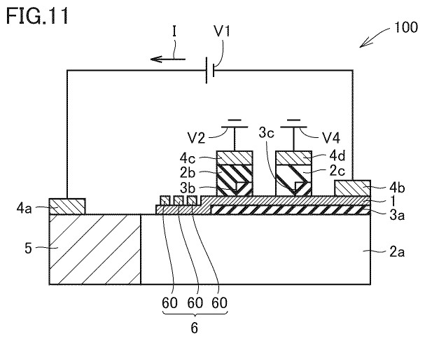

Next, a configuration of electromagnetic wave detector 100 according to Embodiment 9 will be described with reference to FIG. 11. Unless otherwise specified, Embodiment 9 has the same components and the same functions and effects as those of Embodiment 7 described above. Therefore, the same components as those of Embodiment 7 described above have the same reference characters allotted, and description is not repeated.

As shown in FIG. 11, electromagnetic wave detector 100 according to the present embodiment further includes a floating electrode 6. Floating electrode 6 is in contact with two-dimensional material layer 1. Floating electrode 6 is not connected to a power supply circuit or the like.

The material of floating electrode 6 may be determined as appropriate as long as it is a conductor. The material of floating electrode 6 is, for example, a metal such as gold (Au), silver (Ag), copper (Cu), aluminum (Al), nickel (Ni), chromium (Cr), or palladium (Pd). The material of floating electrode 6 may be a material that produces a surface plasmon resonance.

The method of forming floating electrode 6 on two-dimensional material layer 1 may be determined as appropriate. For example, floating electrode 6 may be formed on two-dimensional material layer 1 by the same manufacturing method as the manufacturing method for first electrode portion 4a and second electrode portion 4b.

Floating electrode 6 may include a plurality of floating electrode portions 60. Each of floating electrode portions 60 is a conductor. Floating electrode portions 60 are spaced apart from each other. Floating electrode portions 60 may be disposed to produce a surface plasmon resonance. Floating electrode portions 60 may be spaced apart from each other along a first direction. Floating electrode portions 60 are spaced apart from each other along the first direction and a second direction that is orthogonal to the first direction. The first direction is, for example, a direction from second photosensitizing layer 2b toward third photosensitizing layer 2c on two-dimensional material layer 1. Floating electrode portions 60 may be disposed periodically. Floating electrode portions 60 being disposed periodically means that, in plan view of electromagnetic wave detector 100, for example, floating electrode portions 60 are disposed at positions corresponding to the respective grid points of a square grid, a triangular grid, or any other grid. Floating electrode portions 60 may be disposed to have symmetry in plan view. Floating electrode portions 60 may be disposed asymmetrically in plan view.

The planar shape of each of floating electrode portions 60 is, for example, circular, elliptical, or polygonal such as triangular or square. The planar shape of each of floating electrode portions 60 may be determined as appropriate.

In FIG. 11, floating electrode 6 is disposed opposite to first photosensitizing layer 2a relative to two-dimensional material layer 1, but the arrangement of floating electrode 6 is not limited thereto. Floating electrode 6 may be disposed between two-dimensional material layer 1 and second photosensitizing layer 2b and between two-dimensional material layer 1 and third photosensitizing layer 2c. In this case, the lifetime of the photocarriers generated in second photosensitizing layer 2b and third photosensitizing layer 2c and injected into two-dimensional material layer 1 is improved. As a result, the sensitivity of electromagnetic wave detector 100 can be improved. In addition, floating electrode 6 may be disposed between two-dimensional material layer 1 and first insulating layer 3a.

Although not shown, two-dimensional material layer 1 may further include uneven portions. The uneven portions may be disposed periodically or asymmetrically, similar to floating electrode portions 60. In this case, the same effects as those obtained when floating electrode portions 60 are disposed are obtained.

### <Functions and Effects>

Next, the functions and effects of the present embodiment will be described.

In electromagnetic wave detector 100 according to the present embodiment, as shown in FIG. 11, floating electrode 6 is in contact with two-dimensional material layer 1. Thus, the photocarriers generated by the irradiation with electromagnetic waves in first photosensitizing layer 2a can move back and forth between floating electrode 6 and two-dimensional material layer 1. As a result, the lifetime of the photocarriers can be increased. This can improve the sensitivity of electromagnetic wave detector 100.

The material of floating electrode 6 may be a material that produces a surface plasmon resonance, and floating electrode portions 60 may be disposed so as to produce a surface plasmon resonance. In this case, polarization dependency occurs in floating electrode 6 due to the surface plasmon resonance. This allows only the electromagnetic waves, polarized due to the surface plasmon resonance, to be applied to first photosensitizing layer 2a. This allow electromagnetic wave detector 100 to selectively detect polarized electromagnetic waves.

The material of floating electrode 6 may be a material that causes a surface plasmon resonance, and floating electrode portions 60 may be disposed so as to cause a surface plasmon resonance. In this case, electromagnetic waves can be resonated by the surface plasmon resonance. As a result, electromagnetic wave detector 100 can selectively detect electromagnetic waves.

### Embodiment 10

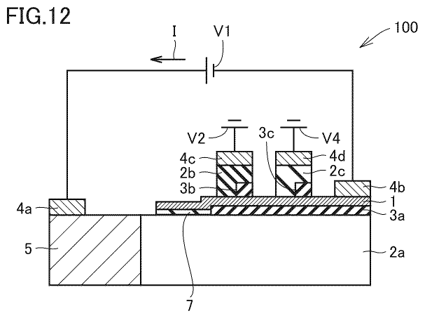

Next, a configuration of electromagnetic wave detector 100 according to Embodiment 10 will be described with reference to FIG. 12. Unless otherwise specified, Embodiment 10 has the same components and the same functions and effects as those of Embodiment 7 described above. Therefore, the same components as those of Embodiment 7 described above have the same reference characters allotted, and description is not repeated.

As shown in FIG. 12, electromagnetic wave detector 100 according to the present embodiment further includes a buffer layer 7. Buffer layer 7 is disposed at least one of between two-dimensional material layer 1 and first photosensitizing layer 2a, between two-dimensional material layer 1 and second photosensitizing layer 2b, and between two-dimensional material layer 1 and third photosensitizing layer 2c. In FIG. 12, buffer layer 7 is disposed between two-dimensional material layer 1 and first photosensitizing layer 2a.

Buffer layer 7 has a thickness that allows formation of a tunnel current at least one of between two-dimensional material layer 1 and first photosensitizing layer 2a, between two-dimensional material layer 1 and second photosensitizing layer 2b, and between two-dimensional material layer 1 and third photosensitizing layer 2c. In the present embodiment, buffer layer 7 has a thickness that allows formation of a tunnel current between two-dimensional material layer 1 and first photosensitizing layer 2a. Buffer layer 7 is an insulating film having a thickness of 1 nm or more and 10 nm or less. Buffer layer 7 is thinner than a first insulating film. The material of buffer layer 7 is, for example, a metal oxide such as alumina (aluminum oxide) or hafnium oxide (HfO₂), a semiconductor oxide such as silicon oxide, or a semiconductor nitride such as silicon nitride (Si₃N₄). The material of buffer layer 7 may be boron nitride.

The method of producing buffer layer 7 may be determined as appropriate, and may be selected from, for example, atomic layer deposition (ALD), vacuum deposition, sputtering, and any other method. Buffer layer 7 may also be formed by oxidizing or nitriding the surface of first photosensitizing layer 2a. Buffer layer 7 may also be a natural oxide film formed on the surface of first photosensitizing layer 2a.

In FIG. 12, buffer layer 7 is provided only between first photosensitizing layer 2a and two-dimensional material layer 1, but buffer layer 7 may be provided between second photosensitizing layer 2b and two-dimensional material layer 1 or between third photosensitizing layer 2c and two-dimensional material layer 1. In this case, the thickness of buffer layer 7 is preferably a thickness that causes tunneling injection from second photosensitizing layer 2b to two-dimensional material layer 1 and a thickness that causes tunneling injection from third photosensitizing layer 2c to two-dimensional material layer 1.

### <Functions and Effects>

Next, the functions and effects of the present embodiment will be described.

According to the present embodiment, as shown in FIG. 12, electromagnetic wave detector 100 further includes buffer layer 7. Buffer layer 7 is disposed at least one of between two-dimensional material layer 1 and first photosensitizing layer 2a, between two-dimensional material layer 1 and second photosensitizing layer 2b, and between two-dimensional material layer 1 and third photosensitizing layer 2c. This can suppress a leakage current at the junction interface between two-dimensional material layer 1 and first photosensitizing layer 2a, second photosensitizing layer 2b, third photosensitizing layer 2c. Thus, a dark current can be reduced.

Buffer layer 7 has a thickness that allows formation of a tunnel current at least one of between two-dimensional material layer 1 and first photosensitizing layer 2a, between two-dimensional material layer 1 and second photosensitizing layer 2b, and between two-dimensional material layer 1 and third photosensitizing layer 2c. As a result, a large photocurrent is injected into two-dimensional material layer 1 as the injection efficiency is improved by the tunnel current. This can improve the sensitivity of electromagnetic wave detector 100.

### Embodiment 11

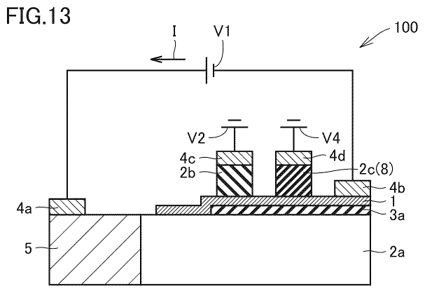

Next, a configuration of electromagnetic wave detector 100 according to Embodiment 2 will be described with reference to FIGS. 13 to 17. Unless otherwise specified, Embodiment 2 has the same components and the same functions and effects as those of Embodiment 1 described above. Therefore, the same components as those of Embodiment 1 described above have the same reference characters allotted, and description is not repeated.

As shown in FIG. 13, third photosensitizing layer 2c of electromagnetic wave detector 100 according to the present embodiment includes a ferroelectric material 8. Third photosensitizing layer 2c may be formed of ferroelectric material 8. Ferroelectric material 8 is provided on two-dimensional material layer 1. Fourth electrode portion 4d is electrically connected to ferroelectric material 8.

The material of ferroelectric material 8 may be determined as appropriate, as long it is a material that brings about polarization for the detection wavelength. The material of ferroelectric material 8 may include, for example, at least one of barium titanate (BaTiO₃), lithium niobate (LiNbO₃), lithium tantalate (LiTaO₃), strontium titanate (SrTiO₃), lead zirconate titanate (PZT), strontium bismuth tantalate (SBT), bismuth ferrite (BFO), zinc oxide (ZnO), hafnium oxide (HfO₂), and a polyvinylidene fluoride-based ferroelectric (e.g., PVDF, P (VDF-TrFE), P (VDF-TrFE-CTFE)) which is an organic polymer.

Ferroelectric material 8 may be a stack or mixture of different ferroelectrics. The method of producing ferroelectric material 8 may be determined as appropriate. For example, when ferroelectric material 8 includes a polymer-based material, a polymer film is formed by spin coating or any other method, and is then processed by photolithography. When ferroelectric material 8 is any other material, it is formed by sputtering, vapor deposition, MOD coating, or any other method, and is then patterned by photolithography. In addition, a method referred to as lift-off may be used, in which a resist mask is used as a mask and ferroelectric material 8 is formed, and then the resist mask is removed.

The material of ferroelectric material 8 is not limited to the ferroelectric material described above, and may be any pyroelectric substance that exhibits a pyroelectric effect. Specifically, the material of ferroelectric material 8 may be any ferroelectric material that causes a polarization change in response to a change in thermal energy. Since electromagnetic waves simply act as a heat source in the pyroelectric effect, the pyroelectric effect is basically not wavelength-dependent. For this reason, ferroelectric material 8 is sensitive to a wide range of electromagnetic waves.

Desirably, ferroelectric material 8 is designed such that the change rate of dielectric polarization in ferroelectric material 8 is as short as possible. Specifically, the thickness of ferroelectric material 8 is preferably small to the extent that allows application of a voltage to two-dimensional material layer 1.

In addition, ferroelectric material 8 preferably has a film thickness that causes the value of the voltage, which is applied to two-dimensional material layer 1 when two-dimensional material layer 1 is irradiated with electromagnetic waves, to be a maximum value. The polarization direction of ferroelectric material 8 is not particularly limited, but it is desirable that the polarization direction extend along the direction of application of a voltage to two-dimensional material layer 1.

Although not shown, electromagnetic wave detector 100 may further include a Mott insulator which is in contact with ferroelectric material 8 and in which a photoinduced phase transition occurs due to light irradiation, causing a change in physical properties (e.g., temperature).

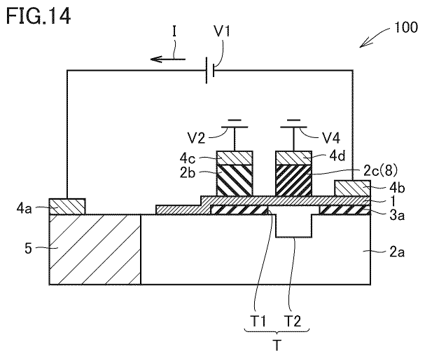

As shown in FIG. 14, first insulating layer 3a may have a through hole T1 opposite to third photosensitizing layer 2c relative to two-dimensional material layer 1. First photosensitizing layer 2a may have a recess T2 opposite to third photosensitizing layer 2c relative to two-dimensional material layer 1. In this case, first insulating layer 3a and first photosensitizing layer 2a form a trench structure T with through hole T1 and recess T2. Two-dimensional material layer 1 has a bridging structure that spans trench structure T.

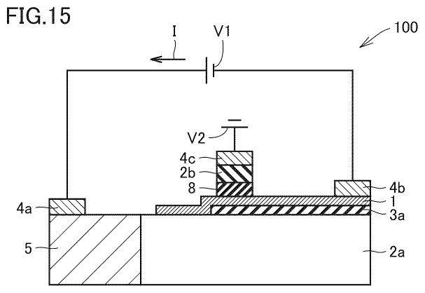

As shown in FIG. 15, second photosensitizing layer 2b may include ferroelectric material 8. Second photosensitizing layer 2b may be formed of ferroelectric material 8. When electromagnetic waves of the detection wavelength of ferroelectric material 8 enter ferroelectric material 8, polarization occurs within ferroelectric material 8. This changes voltage V4 applied from third electrode portion 4c. In other words, in addition to the electric field effect associated with the photocarriers accumulated at the interface between second photosensitizing layer 2b and ferroelectric material 8, a change in voltage value occurs in association with the polarization that has occurred in ferroelectric material 8. This results in a greater photogating effect than when ferroelectric material 8 is not provided. As a result, the amount of the photocurrent generated in two-dimensional material layer 1 increases, and accordingly, electromagnetic wave detector 100 having higher sensitivity is obtained.

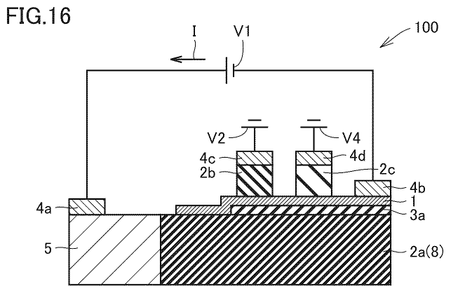

As shown in FIG. 16, first photosensitizing layer 2a may include ferroelectric material 8. First photosensitizing layer 2a may be formed of ferroelectric material 8.

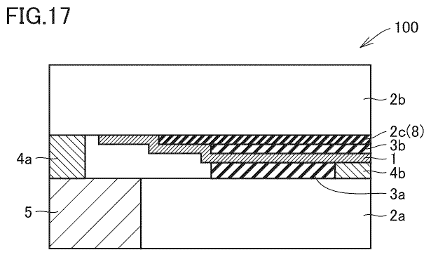

As shown in FIG. 17, ferroelectric material 8 may be disposed between second photosensitizing layer 2b and two-dimensional material layer 1. In other words, ferroelectric material 8 may connect two-dimensional material layer 1 to second photosensitizing layer 2b. When electromagnetic waves of the detection wavelength of the dielectric material enter ferroelectric material 8, polarization occurs within ferroelectric material 8. This changes voltage V2 applied from second electrode portion 4b. In other words, in addition to the electric field effect associated with the photocarriers accumulated at the interface between second photosensitizing layer 2b and ferroelectric material 8, a change in voltage value occurs in association with the polarization that has occurred in ferroelectric material 8. This results in a greater photogating effect than when ferroelectric material 8 is not provided. Consequently, the amount of the photocurrent generated in two-dimensional material layer 1 increases, and accordingly, electromagnetic wave detector 100 having higher sensitivity is obtained.

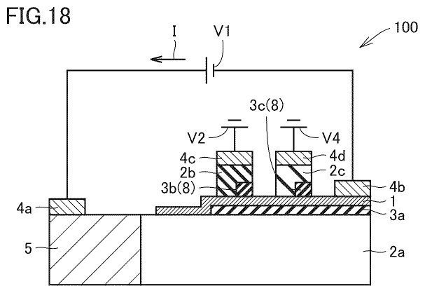

As shown in FIG. 18, at least one of first insulating layer 3a and second insulating layer 3b may include ferroelectric material 8. Third insulating layer 3c may also include ferroelectric material 8. In FIG. 18, second insulating layer 3b and third insulating layer 3c include ferroelectric material 8. At least one of first insulating layer 3a, second insulating layer 3b, and third insulating layer 3c may be formed of ferroelectric material 8. Ferroelectric material 8 may be disposed between first photosensitizing layer 2a and two-dimensional material layer 1.

### <Functions and Effects>

Next, the functions and effects of the present embodiment will be described.

In electromagnetic wave detector 100 according to the present embodiment, as shown in FIGS. 13, 15 and 16, at least one of first photosensitizing layer 2a, second photosensitizing layer 2b, and third photosensitizing layer 2c includes ferroelectric material 8. In this case, as ferroelectric material 8 is irradiated with electromagnetic waves, the dielectric polarization changes inside ferroelectric material 8 due to the pyroelectric effect of ferroelectric material 8. This causes electric charges to be injected from ferroelectric material 8 into two-dimensional material layer 1. As a result, a bias voltage is applied to electromagnetic wave detector 100 in a pseudo manner. Thus, the resistance value of two-dimensional material layer 1 changes. By detecting the change in the resistance value of two-dimensional material layer 1, the electromagnetic waves that have been applied to electromagnetic wave detector 100 can be detected.

Voltage V4 may be applied to ferroelectric material 8 by fourth electrode portion 4d. In this case, the voltage applied to two-dimensional material layer 1 is modulated as the dielectric polarization of ferroelectric material 8 changes due to the pyroelectric effect. Specifically, voltage V4 is modulated so as to become voltage V4+ΔV4. As the applied voltage is modulated, the Fermi level of two-dimensional material layer 1 is modulated. This causes the resistance value of two-dimensional material layer 1 to change.

In other words, a change occurs in the resistance value of two-dimensional material layer 1 due to the electric charges injected from ferroelectric material 8 into two-dimensional material layer 1, and a change occurs in the resistance value due to the Fermi level modulation of two-dimensional material layer 1 associated with the dielectric polarization of ferroelectric material 8. Thus, compared with electromagnetic wave detector 100 including only two-dimensional material layer 1 or only ferroelectric material 8, a greater amount of photocurrent is obtained, thus leading to improved sensitivity of electromagnetic wave detector 100.

More specifically, as shown in FIG. 15, second photosensitizing layer 2b may include ferroelectric material 8. Ferroelectric material 8 may be directly connected to the two-dimensional material layer. When electromagnetic waves of the wavelength to which second photosensitizing layer 2b is sensitive enter second photosensitizing layer 2b, photocarriers are generated in the semiconductor material. When a voltage is applied to second photosensitizing layer 2b, a depletion layer is formed in ferroelectric material 8. The photocarriers generated in the depletion layer provide an electric field effect to two-dimensional material layer 1 via ferroelectric material 8. When electromagnetic waves to which ferroelectric material 8 is sensitive enter ferroelectric material 8, polarization occurs in ferroelectric material 8. As a result, in addition to the electric field effect associated with the photocarriers accumulated at the interface of ferroelectric material 8, a greater photogating effect is produced than when ferroelectric material 8 is not provided, due to the change in voltage value associated with the polarization that has occurred in ferroelectric material 8. Consequently, the amount of the photocurrent generated in two-dimensional material layer 1 increases, thus leading to improved sensitivity of electromagnetic wave detector 100.

As shown in FIG. 14, first insulating layer 3a and first photosensitizing layer 2a form trench structure T with through hole T1 and recess T2. Thus, the thermal capacity of the structure (first insulating layer 3a and first photosensitizing layer 2a) connected to ferroelectric material 8 is reduced. Thus, the amount of temperature change caused by ferroelectric material 8 in electromagnetic wave detector 100 can be increased. This can increase the amount of polarization change caused in ferroelectric material 8, thus increasing the voltage applied to two-dimensional material layer 1. This can improve the sensitivity of electromagnetic wave detector 100.

As shown in FIG. 18, at least one of first insulating layer 3a and second insulating layer 3b may include ferroelectric material 8, and third insulating layer 3c may include ferroelectric material 8. In this case, as ferroelectric material 8 is irradiated with electromagnetic waves, the dielectric polarization changes inside ferroelectric material 8 due to the pyroelectric effect of ferroelectric material 8. This causes charges to be injected from ferroelectric material 8 into two-dimensional material layer 1. Consequently, a bias voltage is applied to electromagnetic wave detector 100 in a pseudo manner. This changes the resistance value of two-dimensional material layer 1. The electromagnetic waves applied to electromagnetic wave detector 100 can be detected by detecting the change in the resistance value of two-dimensional material layer 1.

### Embodiment 12

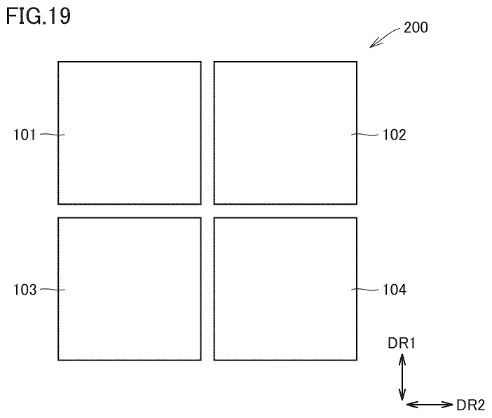

Next, a configuration of an electromagnetic wave detector array according to Embodiment 12 will be described with reference to FIG. 19. Unless otherwise specified, Embodiment 12 has the same components and the same functions and effects as those of Embodiment 1 described above. Therefore, the same components as those of Embodiment 1 described above have the same reference characters allotted, and description is not repeated.

An electromagnetic wave detector array 200 according to the present embodiment includes a plurality of electromagnetic wave detectors 100 according to Embodiments 1 to 11. Electromagnetic wave detectors 100 are disposed side by side along at least one of a first direction DR1 and a second direction DR2 intersecting first direction DR1. In the present embodiment, electromagnetic wave detectors 100 included in electromagnetic wave detector array 200 are the same electromagnetic wave detectors 100.

In electromagnetic wave detector array 200 shown in FIG. 19, four electromagnetic wave detectors 100 are disposed in a 2×2 array, but the number of electromagnetic wave detectors 100 disposed is not limited thereto. For example, nine electromagnetic wave detectors 100 may be disposed in a 3×3 array. In addition, a plurality of electromagnetic wave detectors 100 are disposed periodically in two dimensions in electromagnetic wave detector array 200 shown in FIG. 19, but electromagnetic wave detectors 100 may be disposed periodically along a single direction. In addition, the distance between adjacent electromagnetic wave detectors 100 of electromagnetic wave detectors 100 may be equal to or different from each other.

As long as electromagnetic wave detectors 100 are separated from each other, a single first electrode portion 4a (see FIG. 1) may be used as a common electrode in electromagnetic wave detectors 100. Consequently, the wiring of electromagnetic wave detector array 200 can be reduced compared with the case where first electrode portions 4a are independent of each other, thus increasing the resolution of electromagnetic wave detector array 200.

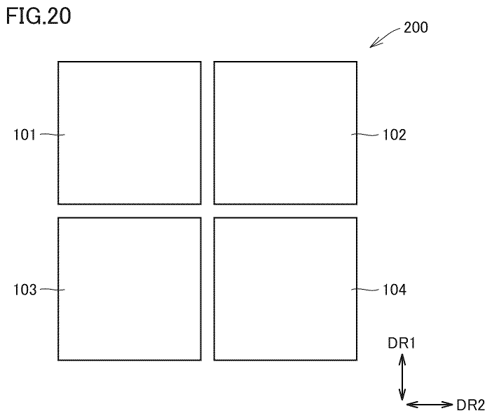

Next, a configuration of a modification of electromagnetic wave detector array 200 according to Embodiment 12 will be described with reference to FIG. 20.

Electromagnetic wave detectors 100 included in electromagnetic wave detector array 200 are electromagnetic wave detectors 101 to 104 of different types.

Electromagnetic wave detectors 101 to 104 of different types are disposed in an array (in a matrix). Electromagnetic wave detectors 101 to 104 may have different detection wavelengths. Specifically, electromagnetic wave detectors 101 to 104 may have different detection wavelength selectivities.

For example, the materials of first photosensitizing layer 2a (see FIG. 9), second photosensitizing layer 2b (see FIG. 9), third photosensitizing layer 2c (see FIG. 9), or ferroelectric material 8 (see FIG. 13) may have different detection wavelengths among electromagnetic wave detectors 101 to 104. In this case, for example, a semiconductor material or ferroelectric material 8 (see FIG. 13) whose detection wavelength is a wavelength of visible light and a semiconductor material or ferroelectric material 8 (see FIG. 13) whose detection wavelength is a wavelength of infrared light may be used. For example, when electromagnetic wave detector array 200 is applied to an in-vehicle sensor, electromagnetic wave detector array 200 can be used as a camera for visible light images during the daytime. Further, electromagnetic wave detector array 200 can also be used as an infrared camera at night. This eliminates the need for using different cameras depending on the detection wavelength of the electromagnetic wave.

### <Functions and Effects>

Next, the functions and effects of the present embodiment will be described.

According to the present embodiment, as shown in FIG. 19, electromagnetic wave detector array 200 includes electromagnetic wave detectors 100 according to Embodiments 1 to 11. Thus, electromagnetic wave detector array 200 can be caused to function as an image sensor by using each of electromagnetic wave detectors 100 as a detection element.

In electromagnetic wave detector array 200 according to the modification of the present embodiment, as shown in FIG. 20, electromagnetic wave detectors 101 to 104 have different detection wavelengths. This allows electromagnetic wave detector array 200 to detect electromagnetic waves of at least two or more different wavelengths.

As a result, electromagnetic wave detector array 200 can distinguish the wavelengths of electromagnetic waves in any wavelength range, such as the wavelength range of ultraviolet light, infrared light, terahertz waves, or radio waves, similarly to image sensors used in the visible light range. As a result, for example, a colorized image can be obtained in which a difference in wavelength is indicated as a difference in color.

In addition, electromagnetic wave detector array 200 may be used as a sensor other than an image sensor. For example, electromagnetic wave detector array 200 can be used as a position detection sensor that can detect the position of an object even with a small number of pixels. In addition, for example, electromagnetic wave detector array 200 may be used as an image sensor that can detect the intensity of electromagnetic waves at a plurality of wavelengths. This enables detection of a plurality of electromagnetic waves without using a color filter that has conventionally been required for a complementary MOS (CMOS) sensor or the like, and accordingly, a colorized image can be obtained.

Electromagnetic wave detectors 101 to 104 are configured to detect electromagnetic waves having different polarizations. This allows electromagnetic wave detector array 200 to function as a polarization-distinction image sensor. For example, polarization imaging is enabled by disposing a plurality of electromagnetic wave detectors 100 in units of four pixels whose polarization angles of detection are 0°, 90°, 45°, 135°, respectively. The polarization-distinction image sensors enable, for example, distinction between a man-made object and a natural object, distinction between materials, distinction between a plurality of objects having the same temperature in the infrared wavelength range, distinction between boundaries between a plurality of objects, or improvement in equivalent resolution.

As described above, electromagnetic wave detector array 200 can detect electromagnetic waves in a wide wavelength range. Electromagnetic wave detector array 200 can also detect electromagnetic waves of different wavelengths.

In each of the embodiments described above, it is preferable that the materials of first photosensitizing layer 2a to third photosensitizing layer 2c, first insulating layer 3a to third insulating layer 3c, buffer layer 7, and ferroelectric material 8 be materials that cause a change in properties when being irradiated with electromagnetic waves, thereby causing a change in potential of two-dimensional material layer 1.

Examples of the material that causes a change in properties when being irradiated with electromagnetic waves and thereby cause a change in potential of two-dimensional material layer 1 include quantum dots, ferroelectric materials, liquid crystal materials, fullerenes, rare earth oxides, semiconductor materials, pn junction materials, metal-semiconductor junction materials, and metal-insulator-semiconductor junction materials. For example, when a ferroelectric material having a polarization effect (pyroelectric effect) due to electromagnetic waves is used for ferroelectric material 8, the polarization changes in the ferroelectric material due to irradiation with electromagnetic waves. As a result, a potential change is caused in two-dimensional material layer 1.

When the materials as described above are used as the materials for first photosensitizing layer 2a and the like, the characteristics of first photosensitizing layer 2a to third photosensitizing layer 2c, first insulating layer 3a to third insulating layer 3c, buffer layer 7, or the ferroelectric layer change due to irradiation with electromagnetic waves. As a result, a potential change is caused in two-dimensional material layer 1.

Description has been given of the example in which the materials that change the characteristics by being irradiated with electromagnetic waves to cause a change in potential of two-dimensional material layer 1 are applied to first photosensitizing layer 2a to third photosensitizing layer 2c, first insulating layer 3a to third insulating layer 3c, buffer layer 7, or the ferroelectric layer. However, it is only required to apply, to at least one or more of the above-mentioned members, a material that causes a change in potential change of two-dimensional material layer 1. For example, when the material that changes the characteristics by being irradiated with electromagnetic waves to cause a change in potential of two-dimensional material layer 1 is applied to buffer layer 7, ferroelectric material 8 does not necessarily have to be in direct contact with two-dimensional material layer 1. For example, as long as a change in potential can be caused in two-dimensional material layer 1, buffer layer 7 may be connected to two-dimensional material layer 1 with an insulating layer or the like in between.

Each of the embodiments described above can be modified or omitted as appropriate. Further, the embodiments described above can be modified variously without departing from the gist thereof in implementation stages. The embodiments described above include inventions at various stages, and various inventions can be extracted by combining a plurality of disclosed constituent elements as appropriate.

It should be understood that the embodiments disclosed herein have been presented for the purpose of illustration and non-restrictive in every respect. It is therefore intended that the scope of the present disclosure is defined by claims, not only by the description above, and encompasses all variations and modifications equivalent in meaning and scope to the claims.

### REFERENCE SIGNS LIST

1 two-dimensional material layer; 2a first photosensitizing layer; 2b second photosensitizing layer; 2c third photosensitizing layer; 3a first insulating layer; 3b second insulating layer; 3c third insulating layer; 4a first electrode portion; 4b second electrode portion; 4c third electrode portion; 4d fourth electrode portion; 5 signal processing circuit; 6 floating electrode; 7 buffer layer; 8 ferroelectric material; 100 electromagnetic wave detector; 200 electromagnetic wave detector array; T trench structure; T1 through hole; T2 recess.

1. An electromagnetic wave detector comprising:
a first photosensitizing layer;
a first electrode portion electrically connected to the first photosensitizing layer;
a first insulating layer provided on the first photosensitizing layer;
a two-dimensional material layer provided on the first insulating layer and electrically connected to the first photosensitizing layer;
a second electrode portion electrically connected to the two-dimensional material layer;
a second photosensitizing layer connected to the two-dimensional material layer; and
a third electrode portion connected to the second photosensitizing layer, wherein
the second photosensitizing layer has an absorption maximum value in a wavelength range different from that of the first photosensitizing layer and causes a voltage change in the wavelength range different from that of the first photosensitizing layer, and
the first insulating layer is disposed between the first photosensitizing layer and the two-dimensional material layer.

2. (canceled)

3. The electromagnetic wave detector according to claim 1, further comprising a second insulating layer,
wherein the second insulating layer is disposed between the second photosensitizing layer and the two-dimensional material layer.

4. The electromagnetic wave detector according to claim 3, wherein a surface of the second photosensitizing layer opposite the two-dimensional material layer is covered with the second insulating layer.

5. The electromagnetic wave detector according to claim 3, wherein at least one of the first insulating layer and the second insulating layer includes a ferroelectric material.

6. The electromagnetic wave detector according to claim 1, further comprising a third photosensitizing layer,
wherein the third photosensitizing layer is connected to the two-dimensional material layer, has an absorption maximum value in an electromagnetic wavelength range different from those of the first photosensitizing layer and the second photosensitizing layer, and causes a voltage change in the wavelength range different from those of the first photosensitizing layer and the second photosensitizing layer.

7. The electromagnetic wave detector according to claim 6, further comprising a fourth electrode portion,
wherein the fourth electrode portion is electrically connected to the third photosensitizing layer.

8. The electromagnetic wave detector according to claim 6, further comprising a third insulating layer,
wherein the third insulating layer is disposed between the third photosensitizing layer and the two-dimensional material layer.

9. The electromagnetic wave detector according to claim 8, wherein a surface of the third photosensitizing layer opposite the two-dimensional material layer is covered with the third insulating layer.

10. The electromagnetic wave detector according to claim 8, wherein the third insulating layer includes a ferroelectric material.

11. The electromagnetic wave detector according to claim 6, wherein at least one of the first photosensitizing layer, the second photosensitizing layer, and the third photosensitizing layer includes a semiconductor.

12. The electromagnetic wave detector according to claim 6, wherein at least one of the first photosensitizing layer, the second photosensitizing layer, and the third photosensitizing layer includes an atomic layer material having a band gap.

13. The electromagnetic wave detector according to claim 6, wherein at least one of the first photosensitizing layer, the second photosensitizing layer, and the third photosensitizing layer includes a ferroelectric material.

14. The electromagnetic wave detector according to claim 13, wherein
the first insulating layer has a through hole provided opposite to the third photosensitizing layer relative to the two-dimensional material layer,
the first photosensitizing layer has a recess provided opposite to the third photosensitizing layer relative to the two-dimensional material layer, and
the first insulating layer and the first photosensitizing layer have a trench structure with the through hole and the recess.

15. The electromagnetic wave detector according to claim 6, further comprising a buffer layer,
wherein the buffer layer is disposed at least one of between the two-dimensional material layer and the first photosensitizing layer, between the two-dimensional material layer and the second photosensitizing layer, and between the two-dimensional material layer and the third photosensitizing layer.

16. The electromagnetic wave detector according to claim 15, wherein the buffer layer has a thickness that allows formation of a tunnel current at least one of between the two-dimensional material layer and the first photosensitizing layer, between the two-dimensional material layer and the second photosensitizing layer, and between the two-dimensional material layer and the third photosensitizing layer.

17. The electromagnetic wave detector according to claim 1, wherein the first electrode portion, the first photosensitizing layer, the two-dimensional material layer, and the second electrode portion are electrically connected in this order.

18. The electromagnetic wave detector according to claim 1, further comprising a signal processing circuit,
wherein the signal processing circuit is disposed between the first photosensitizing layer and the first electrode portion.

19. The electromagnetic wave detector according to claim 1, further comprising a floating electrode,
wherein the floating electrode is in contact with the two-dimensional material layer.

20. The electromagnetic wave detector according to claim 1, wherein the two-dimensional material layer includes a turbostratic structure portion.

21. (canceled)

22. An electromagnetic wave detector array comprising a plurality of the electromagnetic wave detectors according to claim 1,
wherein the plurality of electromagnetic wave detectors are disposed side by side in at least one of a first direction and a second direction intersecting the first direction.
